(19) United States
(12) Patent Application Publication
(10) Pub. No.: US 2025/0048622 A1
(43) Pub. Date: Feb. 6, 2025

(54) SEMICONDUCTOR MEMORY DEVICE

(71) Applicant: Samsung Electronics Co., Ltd., Suwon-si (KR)

(72) Inventors: Hyun Geun CHOI, Suwon-si (KR); Kyung Hwan KIM, Suwon-si (KR); Joong Chan SHIN, Suwon-si (KR)

(73) Assignee: Samsung Electronics Co., Ltd., Suwon-si (KR)

(21) Appl. No.: 18/601,447

(22) Filed: Mar. 11, 2024

(30) Foreign Application Priority Data
Aug. 2, 2023 (KR) 10-2023-0100831

(51) Int. Cl. H10B 12/00

(52) U.S. Cl. CPC H10B 12/50; H10B 12/09; H10B 12/315; H10B 12/482

(57) ABSTRACT

A semiconductor memory device may include includes a bit line and a back gate strap line extending on a substrate, an active pattern on the bit line and the back gate strap line, a word line on a first side wall of the active pattern, a back gate electrode on a second side wall of the active pattern and connected to the back gate strap line, a data storage pattern connected to a face of the active pattern, and a word line contact plug connected to the word line. A first face of the back gate electrode and a first face of the word line may face the bit line and the back gate strap line. The first face of the back gate electrode may be connected to the back gate strap line. A second face of the word line may be connected to the word line contact plug.

### CROSS-REFERENCE TO RELATED APPLICATION

This application claims priority from Korean Patent Application No. 10-2023-0100831, filed on Aug. 2, 2023 in the Korean Intellectual Property Office, and all the benefits accruing therefrom under 35 U.S.C. 119, the entire contents of which are herein incorporated by reference.

### BACKGROUND

### Technical Field

The present disclosure relates to a semiconductor memory device, and more particularly, to a semiconductor memory device including a vertical channel transistor (VCT).

### Description of the Related Art

There is a need to increase the degree of integration of a semiconductor memory device so as to satisfy excellent performance and low price required by consumers. Because the degree of integration in the case of the semiconductor memory device may be an important factor in determining the price of a product, an increased degree of integration particularly may be required.

In the case of a two-dimensional or planar semiconductor memory device, the degree of integration mainly may be determined by an area occupied by unit memory cells, and therefore may be greatly affected by the level of fine pattern forming technology. However, since ultra-expensive apparatuses may be required to miniaturize the pattern, the degree of integration of the two-dimensional semiconductor memory device may be increasing, but still may be limited. Accordingly, semiconductor memory devices that include a vertical channel transistor whose channel extends vertically are being proposed.

### SUMMARY

Aspects of the present disclosure provide a semiconductor memory device having improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a semiconductor memory device may include a substrate; a bit line extending in a first direction on the substrate; a back gate strap line on the substrate and extending in the first direction; an active pattern on the bit line and the back gate strap line, the active pattern including a first side wall and a second side wall opposite each other in the first direction, a first face of the active pattern being opposite a second face of the active pattern in a vertical direction, the first face of the active pattern being connected to the bit line; a word line on the first side wall of the active pattern and extending in a second direction; a back gate electrode on the second side wall of the active pattern and extending in the second direction, the back gate electrode being connected to the back gate strap line; a data storage pattern connected to the second face of the active pattern; and a word line contact plug connected to the word line. A first face of the back gate electrode and a second face of the back gate electrode may be opposite each other in the vertical direction. A first face of the word line and a second face of the word line may be opposite each other in the vertical direction. The first face of the back gate electrode and the first face of the word line each may face the bit line and the back gate strap line. The first face of the back gate electrode may be connected to the back gate strap line, and the second face of the word line may be connected to the word line contact plug.

According to an embodiment of the present disclosure, a semiconductor memory device may include a substrate; bit lines extending in a first direction on the substrate; a first back gate strap line on the substrate, the first back gate strap line extending in the first direction; back gate electrodes on the bit lines and the first back gate strap line, the back gate electrodes extending in a second direction; a first word line and a second word line on the bit line and the first back gate strap line, the first word line and the second word line between the back gate electrodes adjacent to each other in the first direction, and the first word line the second word line extending in the second direction; first active patterns between the back gate electrode and the first word line, the first active patterns arranged in the second direction; second active patterns between the back gate electrode and the second word line, the second active patterns arranged in the second direction; a back gate contact plug between the first back gate strap line and one or more back gate electrodes, and the back gate contact plug connecting the first back gate strap line and the back gate electrode to each other; a word line contact plug on the first word line and connected to the first word line; and a data storage pattern on the first active pattern and the second active pattern, the data storage pattern connected to the first active pattern and the second active pattern. The first word line may be between the word line contact plug and the first back gate strap line.

According to an embodiment of the present disclosure, a semiconductor memory device may include a substrate; a peri-gate structure on the substrate; a shielding conductive pattern on the peri-gate structure, the shielding conductive pattern including a shielding conductive plate and a plurality of shielding conductive protruding parts protruding from the shielding conductive plate, each of the shielding conductive protruding parts extending in a first direction; a first back gate strap line and a second back gate strap line on the shielding conductive pattern and extending in the first direction; bit lines between the first back gate strap line and the second back gate strap line, the bit lines on the shielding conductive pattern and extending in the first direction; back gate electrodes on the bit line, the first back gate strap line, and the second back gate strap line, the back gate electrodes extending in a second direction; a first word line and a second word line between the back gate electrodes adjacent to each other in the first direction, the first word line and the second word line being on the bit line, the first back gate strap line and the second back gate strap line, and the first word line and the second word line extending in the second direction; first active patterns between the back gate electrode and the first word line, the first active patterns being connected to the bit line and arranged in the second direction; second active patterns between the back gate electrode and the second word line, the second active patterns being connected to the bit line and arranged in the second direction; a first back gate contact plug between the first back gate strap line and a part of the back gate electrodes, the first back contact plug connecting the first back gate strap line and the back gate electrode to each other; a second back gate contact plug between the second back gate strap line and a rest of the back gate electrode, the second back contact plug connecting the second back gate strap line and the back gate electrode to each other; a word line contact plug on the first word line and connected to the first word line; and a data storage pattern on the first active pattern and the second active pattern, the data storage pattern being connected to the first active pattern and the second active pattern. The first word line may include a first face and a second face opposite each other in a vertical direction. The first face of the first word line may face the bit line. The word line contact plug may be connected to the second face of the first word line.

### BRIEF DESCRIPTION OF THE DRAWINGS

FIG. 1 is a layout diagram of a semiconductor memory device according to some embodiments.

FIG. 2 is a layout diagram of a boundary portion between a cell array region and a peripheral circuit region of FIG. 1.

FIG. 3 is a cross-sectional view taken along A-A and B-B of FIG. 2.

FIG. 4 is a cross-sectional view taken along C-C and D-D of FIG. 2.

FIG. 5 is a cross-sectional view taken along a portion E-E of FIG. 2.

FIG. 6 is an enlarged view of a portion P of FIG. 4.

FIG. 7 is an enlarged view of a portion Q of FIG. 4.

FIGS. 8 to 11 are enlarged views of a portion R of FIG. 5.

FIG. 12 is an example diagram for explaining a shape in which back gate electrodes and a back gate strap line are connected in the cell array region.

FIGS. 13 and 14 are diagrams for explaining a semiconductor memory device according to some embodiments.

FIGS. 15 and 16 are diagrams for explaining a semiconductor memory device according to some embodiments.

FIGS. 17 to 19 are diagrams for explaining a semiconductor memory device according to some embodiments.

FIGS. 20 to 22 are diagrams for explaining the semiconductor memory device according to some embodiments.

FIGS. 23 and 24 are diagrams for explaining the semiconductor memory device according to some embodiments, respectively.

FIGS. 25 and 26 are diagrams for explaining the semiconductor memory device according to some embodiments.

FIGS. 27 to 30 are diagrams for explaining a semiconductor memory device according to some embodiments.

FIGS. 31 to 63 are diagrams for explaining a method for fabricating a semiconductor memory device according to some embodiments.

### DETAILED DESCRIPTION

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within technical ideas of the present disclosure.

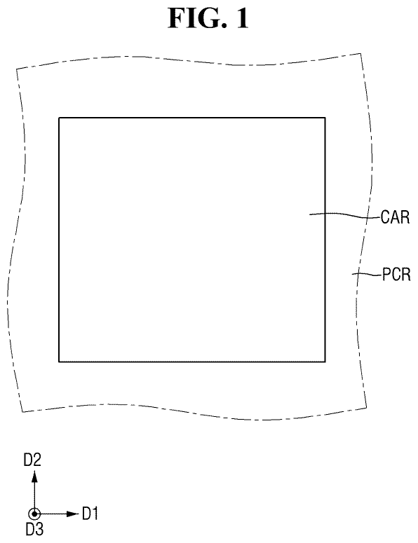

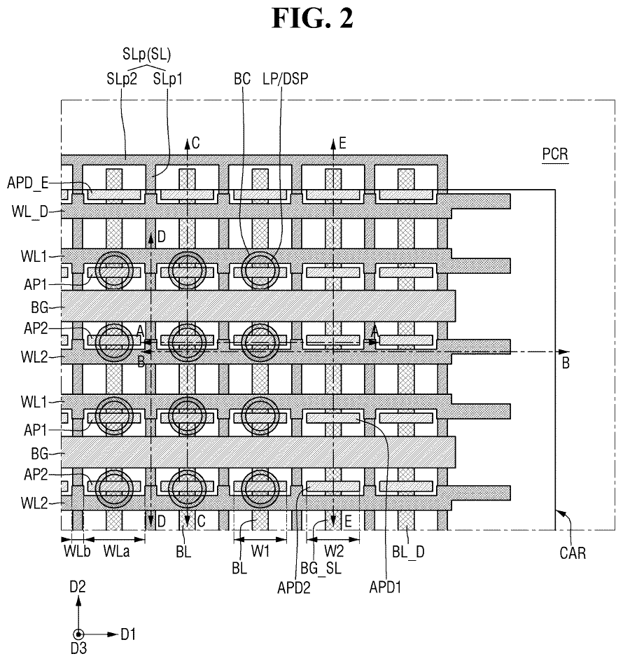

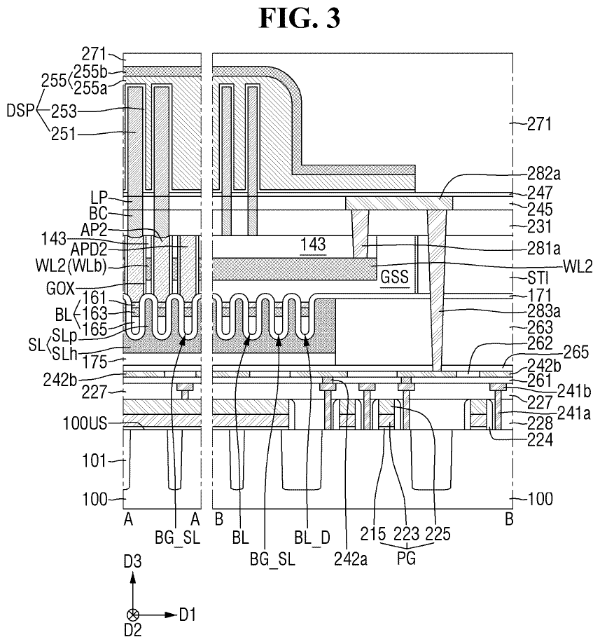

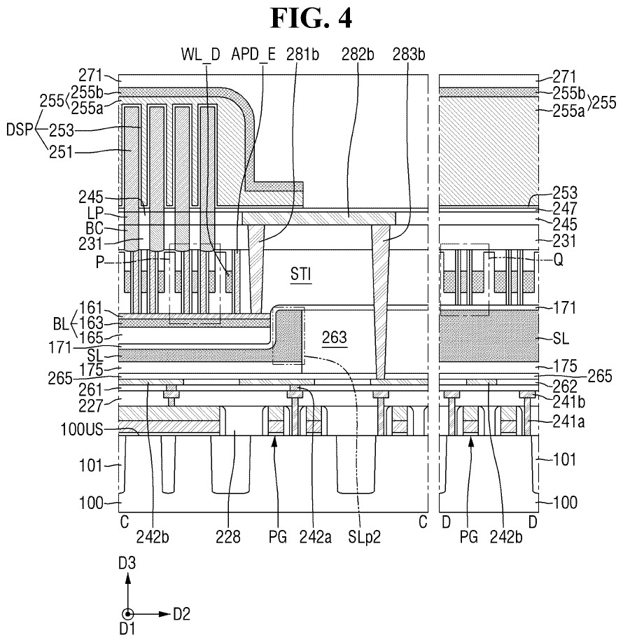

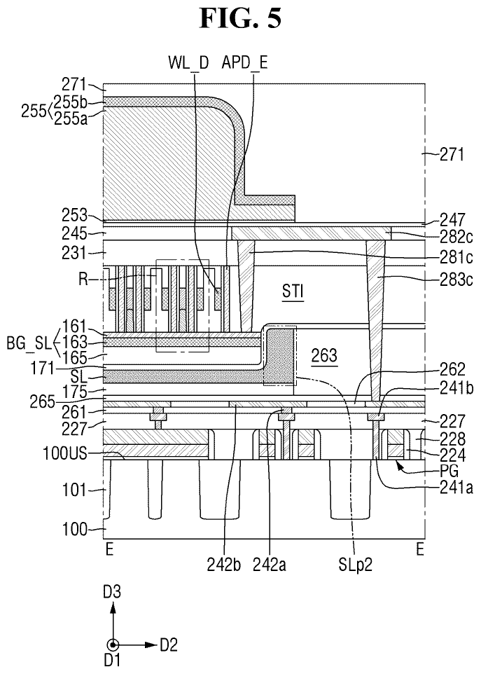

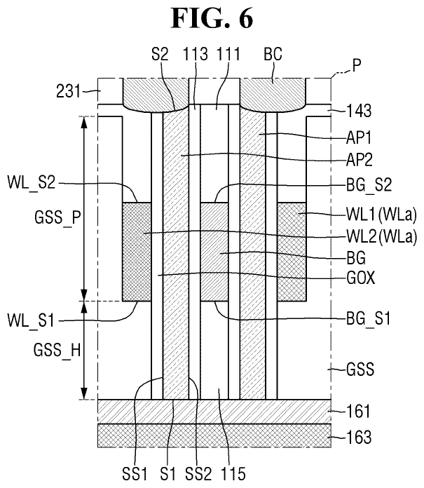

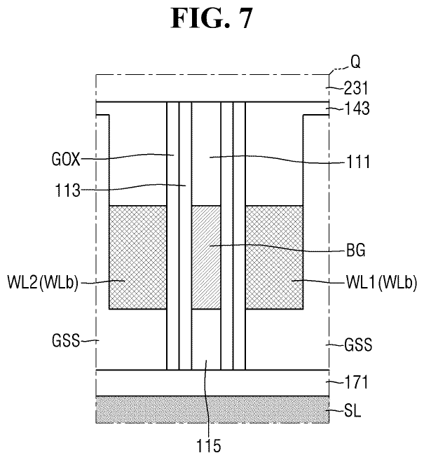

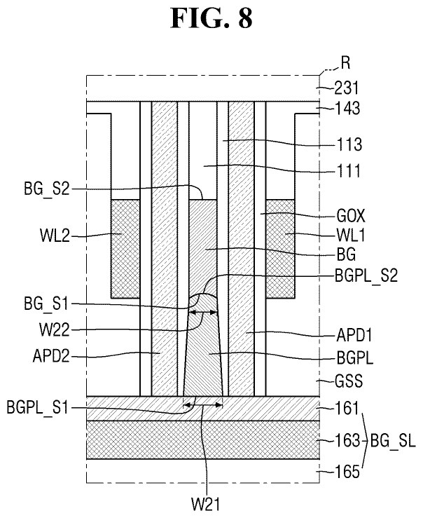

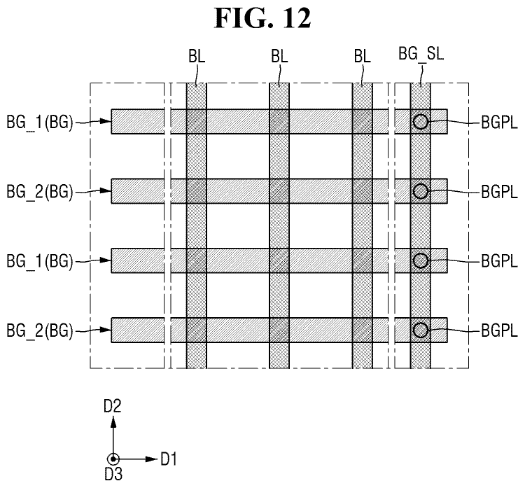

FIG. 1 is a layout diagram of a semiconductor memory device according to some embodiments. FIG. 2 is a layout diagram of a boundary portion between a cell array region and a peripheral circuit region of FIG. 1. FIG. 3 is a cross-sectional view taken along A-A and B-B of FIG. 2. FIG. 4 is a cross-sectional view taken along C-C and D-D of FIG. 2. FIG. 5 is a cross-sectional view taken along a portion E-E of FIG. 2. FIG. 6 is an enlarged view of a portion P of FIG. 4. FIG. 7 is an enlarged view of a portion Q of FIG. 4. FIGS. 8 to 11 are enlarged views of a portion R of FIG. 5. FIG. 12 is an example diagram for explaining a shape in which back gate electrodes and a back gate strap line are connected in the cell array region.

The semiconductor memory device according to an embodiment of the present disclosure may include memory cells including a vertical channel transistor (VCT).

Referring to FIGS. 1 to 12, the semiconductor memory device according to some embodiments may include bit lines BL, word lines WL1 and WL2, back gate electrodes BG, a shielding conductive pattern SL, a back gate strap line BG_SL, active patterns AP1 and AP2, and data storage patterns DSP.

The substrate 100 may be a silicon substrate, or may include other materials, for example, but are not limited to, silicon germanium, indium antimonide, lead telluride, indium arsenide, indium phosphide, gallium arsenide or gallium antimonide.

The substrate 100 may include an upper face 100US. An element separation film 101 may be disposed in the substrate 100. The element separation film 101 may define an active region inside the substrate 100. The element separation film 201 includes an insulating material.

The substrate 100 may include a cell array region CAR in which a data storage pattern DSP is disposed, and a peripheral circuit region PCR defined around the cell array region CAR. A cell region element separation film STI may be disposed on the peripheral circuit region PCR of the substrate 100. From the viewpoint of a plan view, the cell region element separation film STI may define the cell array region CAR of the substrate 100.

A peri-gate structure PG may be disposed on the substrate 100. For example, the peri-gate structure PG may be disposed on the upper face 100US of the substrate. The peri-gate structure PG may be disposed over the cell array region CAR and the peripheral circuit region PCR. In other words, a part of the peri-gate structure PG may be disposed in the cell array region CAR of the substrate 100, and the rest of the peri-gate structure PG may be disposed in the peripheral circuit region PCR of the substrate 100.

The peri-gate structure PG may be included in a sensing transistor, a transfer transistor, a driving transistor, and the like. For example, the peri-gate structure PG included in the sensing transistor may be disposed on the substrate 100 of the cell array region CAR, but is not limited thereto. It goes without saying that the types of transistors of the peripheral circuits disposed on the substrate 100 of the cell array region CAR may vary depending on the design layout of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a dielectric constant higher than that of the silicon oxide film or a combination thereof. The high dielectric constant insulating film may include, for example, but not limited to, at least one of metal oxide, metal oxynitride, metal silicon oxide, and metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, a conductive metal nitride, a conductive metal silicon nitride, a metal carbonitride, a conductive metal silicide, a conductive metal oxide, a two-dimensional material (2D material), and a metal. In the semiconductor device according to some embodiments, the two-dimensional material may be a metallic material and/or a semiconductor material. The 2D material may include a 2D allotrope or a 2D compound, and may include, for example, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the semiconductor memory device of the present disclosure are not limited by the above-mentioned materials. Although the peri-gate structure PG is shown to include a plurality of conductive patterns, the embodiment is not limited thereto.

A peri-gate spacers 224 may be disposed on the side walls of the peri-gate structure PG. The peri-gate spacer 224 includes an insulating material.

Although not shown, the peri-gate structure PG may further include a peri-gate mask pattern disposed on the peri-upper conductive pattern 225. The peri-gate mask pattern is made of an insulating material.

The first peri-lower insulating film 227 and the second peri-lower insulating film 228 are disposed on the upper face 100US of the substrate. The first peri-lower insulating film 227 and the second peri-lower insulating film 228 each include an insulating material.

A peri-contact plug 241a and a peri-wiring line 241b may be disposed inside the first peri-lower insulating film 227 and the second peri-lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different films from each other, the embodiment is not limited thereto. The boundary between the peri-contact plug 241a and the peri-wiring line 241b may not be distinguished. The peri-contact plug 241a and the peri-wiring line 241b each include a conductive material.

The first peri-upper insulating film 261 and the second peri-upper insulating film 262 may be disposed on the peri-contact plug 241a and the peri-wiring line 241b. The first peri-upper insulating film 261 and the second peri-upper insulating film 262 each include an insulating material. Needless to say, an insulating film made of a single film may be disposed on the peri-contact plug 241a and the peri-wiring line 241b, unlike the shown example.

The peri-connection structures 242a and 242b may be connected to the peri-wiring line 241b. The peri-connection structures 242a and 242b may include a peri-connection via 242a and a peri-connection wiring 242b. The peri-connection via 242a and the peri-connection wiring 242b each include a conductive material.

Although the peri-connection via 242a and the peri-connection wiring 242b are shown as being different films from each other, the embodiment is not limited thereto. Although the peri-connection structures 242a and 242b are shown to include one peri-connection wiring 242b disposed at one metal level, this is only for convenience of explanation, and the embodiment is not limited thereto. The peri-connection structures 242a and 242b may include a plurality of peri-connection wirings 242b disposed at different metal levels from each other.

A third peri-upper insulating film 265 may be disposed on the peri-connection structures 242a and 242b. The third peri-upper insulating film 265 includes an insulating material.

Shielding structures 171, SL, and 175 may be disposed on the substrate 100. For example, the shielding structures 171, SL, and 175 may be disposed on the peri-connection structures 242a and 242b.

The shielding structures 171, SL and 175 may include a shielding conductive pattern SL and shielding insulation films 171 and 175. The shielding insulation films 171 and 175 may include a shielding insulation liner 171 and a shielding insulation capping film 175.

The shielding conductive pattern SL may include a shielding conductive plate SLh and a shielding conductive protruding pattern SLp. The shielding conductive plate SLh may have a flat plate shape. The shielding conductive plate SLh may be disposed on the cell array region CAR. A part of the shielding conductive plate SLh may extend over the peripheral circuit region PCR.

The shielding conductive protruding pattern SLp may protrude from the shielding conductive plate SLh in a third direction D3. The shielding conductive protruding pattern SLp may include a plurality of shielding conductive protruding parts SLp1 and a shielding conductive connecting part SLp2. For example, the third direction D3 may be a vertical direction perpendicular to the substrate 100.

Each shielding conductive protruding part SLp1 may protrude toward word lines WL1 and WL2. Each of the shielding conductive protruding part SLp1 may extend in the second direction D2. Each shielding conductive protruding part SLp may be adjacent in the first direction D1. The shielding conductive connecting part SLp2 may connect the shielding conductive protruding parts SLp1 spaced apart in the first direction D1. For example, the first direction D1 and the second direction D2 may be a horizontal direction that is horizontal to the substrate 100.

The shielding insulation capping film 175 may be disposed on the third peri-upper insulating film 265. The shielding insulation capping film 175 may be disposed between the third peri-upper insulating film 265 and the shielding conductive pattern SL.

The shielding insulation liner 171 may be disposed on the shielding conductive pattern SL. The shielding insulation liner 171 may extend along the profiles of the shielding conductive plate SLh and the shielding conductive protruding pattern SLp. The shielding insulation liner 171 does not extend along the side walls of the shielding conductive pattern SL. The side walls of the shielding conductive pattern SL may define a boundary of the shielding conductive pattern SL. The shielding conductive pattern SL may be disposed between the shielding conductive liner 171 and the shielding insulation capping film 175.

A part of the shielding insulation liner 171 may extend along the upper face of the first upper insulating film 263. The first upper insulating film 263 may be disposed on the third peri-upper insulating film 265. The first upper insulating film 263 may cover the side walls of the shielding insulation capping film 175 and the side walls of the shielding conductive pattern SL.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, two-dimensional material and metal. The shielding insulation liner 171, the shielding insulation capping film 175 and the first upper insulating film 263 each include an insulating material. Depending on the materials included in the shielding insulation liner 171 and the first upper insulating film 263, the boundary between the shielding insulation liner 171 and the first upper insulating film 263 may not be distinguished.

Bit lines BL may be disposed on the substrate 100. The bit lines BL may be disposed on the shielding conductive pattern SL. The bit line BL may extend long in the second direction D2. Adjacent bit lines BL may be spaced apart in the first direction D1.

Each bit line BL may be disposed on the shielding conductive plate SLh. The bit line BL may be disposed between the shielding conductive protruding parts SLp1 adjacent in the first direction D1. For example, each bit line BL may be surrounded by the shielding conductive protruding part SLp1 and the shielding conductive connecting part SLp2.

Each bit line BL may extend from the cell array region CAR to the peripheral circuit region PCR. An end portion of each bit line BL may be disposed on the peripheral circuit region PCR. A part of the bit line BL may overlap the cell region element separation film STI that surrounds the cell array region CAR in the third direction D3.

A back gate strap line BG_SL and a dummy bit line BL_D may be disposed on the substrate 100. The back gate strap line BG_SL and the dummy bit line BL_D may be disposed on the shielding conductive pattern SL.

The back gate strap line BG_SL and the dummy bit line BL_D may each extend in the second direction D2. The back gate strap line BG_SL may be disposed between the dummy bit line BL_D and the bit line BL. For example, the dummy bit line BL_D may be disposed at an outer part of the cell array region CAR than the back gate strap line BG_SL.

The back gate strap line BG_SL and the dummy bit line BL_D may be disposed on the shielding conductive plate SLh. The back gate strap line BG_SL and the dummy bit line BL_D may be disposed between the shielding conductive protruding parts SLp1 adjacent to each other in the first direction D1. For example, the back gate strap line BG_SL and the dummy bit line BL_D may be surrounded by the shielding conductive protruding part SLp1 and the shielding conductive connecting part SLp2. Unlike the shown example, the shielding conductive projection SLp1 is disposed on one side of the dummy bit line BL_D, but the shielding conductive projection SLp1 may not be disposed on the other side of the dummy bit line BL_D.

The back gate strap line BG_SL and the dummy bit line BL_D may each extend from the cell array region CAR to the peripheral circuit region PCR. The end portion of the back gate strap line BG_SL and the end portion of the dummy bit line BL_D may be disposed on the peripheral circuit region PCR.

For example, the dummy bit line BL_D may be disposed in a portion of the cell array region CAR that overlaps the back gate electrodes BG in the third direction D3. Alternatively, a part of the dummy bit line BL_D may overlap the back gate electrode BG in the third direction D3. From the viewpoint of a plan view, the dummy bit line BL_D may intersect the back gate electrode BG.

Unlike the shown example, as an example, a dummy bit line BL_D may be further disposed between the back gate strap line BG_SL and the bit line BL. As another example, a plurality of dummy bit lines BL_D may be disposed outside the back gate strap line BG_SL. As still another example, the dummy bit line BL_D may not be disposed on the cell array region CAR. There may be no dummy bit line BL_D disposed in the outer part the cell array region CAR than the back gate strap line BG_SL.

The bit line BL, the back gate strap line BG_SL, and the dummy bit line BL_D may include a semiconductor pattern 161, a metal pattern 163, and a line mask pattern 165, which are sequentially stacked. The back gate strap line BG_SL has the same structure as the bit line BL. The dummy bit line BL_D has the same structure as the bit line BL.

The bit line BL and the dummy bit line BL_D may include a conductive bit line. The back gate strap line BG_SL may include a conductive strap line. The conductive bit line may be a film including a conductive material among the bit line BL and the dummy bit line BL_D. The conductive strap line may be a film including the conductive material in the back gate strap line BG_SL. The conductive bit line and the conductive strap line may include, for example, a semiconductor pattern 161 and a metal pattern 163.

The structure of the back gate strap line BG_SL will be further described using FIGS. 8 to 10. The structure of the back gate strap line BG_SL described using FIGS. 8 to 10 may be applied to the bit line BL and the dummy bit line BL_D.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, polygermanium, amorphous silicon, amorphous silicon germanium, and amorphous germanium. The metal pattern 163 may include a conductive material including a metal. The metal pattern 163 may include, for example, at least one of a conductive metal nitride, a conductive metal silicon nitride, a metal carbonitride, a conductive metal silicide, a conductive metal oxide, a two-dimensional material, and a metal. The line mask pattern 165 may include an insulating material such as silicon nitride or silicon oxynitride.

The cell region element separation film STI may be disposed on the first upper insulating film 263. The shielding insulation liner 171 may be disposed between the cell region element separation film STI and the first upper insulating film 263. From the viewpoint of a plan view, the cell region element separation film STI may define the cell array region CAR in which the word lines WL1 and WL2, the back gate electrodes BG, the active patterns AP1 and AP2, and the like are disposed. Although the cell region element separation film STI is shown to be a single film, the embodiment is not limited thereto. The cell region element separation film STI includes an insulating material.

The first active patterns AP1 and the second active patterns AP2 may be disposed on each bit line BL. The first active patterns AP1 and the second active patterns AP2 may be alternately disposed along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. The first active pattern AP1 may be spaced apart from the second active pattern AP2 in the second direction D2. The first active patterns AP1 and the second active patterns AP2 may be arranged two-dimensionally along the first direction D1 and the second direction D2 that intersect each other.

For example, the first active pattern AP1 and the second active pattern AP2 may each be made of a single crystal semiconductor material. For example, the first active pattern AP1 and the second active pattern AP2 may each be made of single crystal silicon.

The first active pattern AP1 and the second active pattern AP2 each have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on the first and second faces S1 and S2. Also, the width of the first active pattern AP1 may be equal to the width of the second active pattern AP2.

The width of the first active pattern AP1 and the width of the second active pattern AP2 may range from several nm to several tens of nm. For example, the width of the first active pattern AP1 and the width of the second active pattern AP2 may be, but not limited to, 1 nm to 30 nm or 1 nm to 10 nm. Each length of the first and second active patterns AP1 and AP2 may be greater than the line width of the bit line BL. That is, each length of the first and second active patterns AP1 and AP2 may be greater than the width of the bit line BL in the first direction D1.

Each of the first active pattern AP1 and the second active pattern AP2 includes a first face S1 and a second face S2 that are opposite to each other in the third direction D3. For example, the first faces S1 of the first and second active patterns AP1 and AP2 face the bit line BL. The second faces S2 of the first and second active patterns AP1 and AP2 face the contact pattern BC.

The first faces S1 of the first and second active patterns AP1 and AP2 are connected to the bit lines BL. For example, the first faces S1 of the first and second active patterns AP1 and AP2 may be connected to the semiconductor pattern 161 of the bit line BL. Unlike the shown example, when the semiconductor pattern 161 is omitted, the first faces S1 of the first and second active patterns AP1 and AP2 may be connected to the metal pattern 163. The second faces S2 of the first and second active patterns AP1 and AP2 may be connected to the contact patterns BC.

Each of the first active pattern AP1 and the second active pattern AP2 may include a first side wall SS1 and a second side wall SS2 that are opposite to each other in the second direction D2. The second side wall SS2 of the first active pattern AP1 may face the first side wall SS1 of the second active pattern AP2.

The second side wall SS2 of the first active pattern AP1 may be adjacent to the first word line WL1. The first side wall SS1 of the second active pattern AP2 may be adjacent to the second word line WL2.

Although not shown, as an example, each of the first active pattern AP1 and the second active pattern AP2 has a first dopant region adjacent to the bit line BL, and a second dopant region adjacent to the contact pattern BC. Each of the first active pattern AP1 and the second active pattern AP2 may include a channel region between the first dopant region and the second dopant region. The first dopant region and the second dopant region are regions in which dopants are doped in the first active pattern AP1 and the second active pattern AP2. Unlike the above example, each of the first active pattern AP1 and the second active pattern AP2 may not include at least one of the first dopant region and the second dopant region.

During operation of the semiconductor memory device, the channel regions of the first and second active patterns AP1 and AP2 may be controlled by the first and second word lines WL1 and WL2 and the back gate electrodes BG. Since the first and second active patterns AP1 and AP2 are made of a single crystal semiconductor material, leakage current characteristics of the semiconductor memory device can be improved.

The first dummy active patterns APD1 and the second dummy active patterns APD2 may each be disposed on the back gate strap line BG_SL and the dummy bit line BL_D. The first dummy active patterns APD1 and the second dummy active patterns APD2 may be alternately disposed along the second direction D2.

The first dummy active pattern APD1 may be spaced apart from the first active pattern AP1 in the first direction D1. The first active pattern AP1 and the first dummy active pattern APD1 may be arranged in the first direction D1. The second dummy active pattern APD2 may be spaced apart from the second active pattern AP2 in the first direction D1. The second active pattern AP2 and the second dummy active pattern APD2 may be arranged in the first direction D1.

The first dummy active pattern APD1 and the second dummy active pattern APD2 may each be in contact with the back gate strap line BG_SL. The first dummy active pattern APD1 and the second dummy active pattern APD2 may be in contact with the conductive strap line of the back gate strap line BG_SL. Although not shown, the first dummy active pattern APD1 and the second dummy active pattern APD2 may be in contact with the dummy bit line BL.

When the second active pattern AP2 and the second dummy active pattern APD2 will be described as an example, a length W1 of the second active pattern AP2 in the first direction D1 may be equal to a length W2 of the second dummy active pattern APD2 in the first direction D1.

Unlike the shown example, the lengths of the dummy active patterns APD1 and APD2 connected to the dummy bit line BL may be different from the lengths of the dummy active patterns APD1 and APD2 connected to the back gate strap line BG_SL. The second active pattern AP2 and the second dummy active pattern APD2 will be described as an example. The length of the second dummy active pattern APD2 connected to the back gate strap line BG_SL may be the same as the length of the second active pattern AP2 connected to the bit line BL. However, the length of the second dummy active pattern APD2 connected to the dummy bit line BL may differ from the length of the second active pattern AP2 connected to the bit line BL.

In the semiconductor memory device according to some embodiments, the first dummy active pattern APD1 and the second dummy active pattern APD2 may not be connected to the data storage pattern DSP.

The description of the first dummy active pattern APD1 and the second dummy active pattern APD2 may be substantially the same as the description of the first active pattern AP1 and the second active pattern AP2.

In the semiconductor memory device according to some embodiments, boundary dummy active patterns APD_E may be disposed along the boundary of the cell array region CAR. For example, the boundary dummy active patterns APD_E may be in contact with the cell region element separation film STI.

The boundary dummy active patterns APD_E may be spaced apart in the first direction D1. The boundary dummy active patterns APD_E may be arranged in the first direction D1. The dummy active pattern AP_D may not be connected the data storage pattern DSP.

The back gate electrodes BG may be disposed on the bit line BL and the shielding conductive pattern SL. The back gate electrodes BG may be disposed on the back gate strap line BG_SL and the dummy bit line BL_D.

The back gate electrodes BG may be spaced apart from each other in the second direction D2. The back gate electrodes BG may be spaced apart at regular intervals. Each back gate electrode BG may extend in the first direction D1 across the bit line BL.

Each back gate electrode BG may be disposed between the first active pattern AP1 and the second active pattern AP2 adjacent to each other in the second direction D2. That is to say, the first active pattern AP1 may be disposed on one side of each back gate electrode BG, and the second active pattern AP2 may be disposed on the other side of each back gate electrode BG. The height of the back gate electrode BG in the third direction D3 may be smaller than the heights of the first and second active patterns AP1 and AP2.

Each back gate electrode BG may be disposed between the first side wall SS1 of the first active pattern AP1 and the second side wall SS2 of the second active pattern AP2. Each back gate electrode BG may be disposed on the first side wall SS of the first active pattern AP1 and the second side wall SS2 of the second active pattern AP2.

The first active pattern AP1 may be disposed between the first word line WL1 and the back gate electrode BG. The second active pattern AP2 may be disposed between the second word line WL2 and the back gate electrode BG. A pair of first word line WL1 and second word line WL2 may be disposed between the back gate electrodes BG adjacent in the second direction D2.

In the semiconductor memory device according to some embodiments, the first dummy active pattern APD1 may be disposed between the first word line WL1 and the back gate electrode BG. The second dummy active pattern APD2 may be disposed between the second word line WL2 and the back gate electrode BG.

The back gate electrode BG may include a first face BG_S1 and a second face BG_S2 that are opposite to each other in the third direction D3. The first face BG_S1 of the back gate electrode is closer to the bit line BL than the second face BG_S2 of the back gate electrode. The first face BG_S1 of the back gate electrode may face the bit line BL and the back gate strap line BG_SL.

The back gate electrode BG includes a conductive material, and may include, for example, at least one of a conductive semiconductor material, conductive metal nitride, conductive metal silicon nitride, metal carbonitride, conductive metal silicide, conductive metal oxide, a two-dimensional material, and a metal.

A voltage may be applied to the back gate electrode BG during operation of the semiconductor memory device to adjust a threshold voltage of the vertical channel transistor. The threshold voltage of the vertical channel transistor is adjusted, and deterioration of leakage current characteristics may be prevented.

The back gate separation pattern 111 may be disposed between the first active pattern AP1 and the second active pattern AP2 adjacent to each other in the second direction D2. The back gate separation pattern 111 may extend in the first direction D1 along with the back gate electrode BG. The back gate separation pattern 111 may be disposed on the second face BG_S2 of the back gate electrode.

The back gate separation pattern 111 may include, for example, a silicon oxide film, a silicon oxynitride film or a silicon nitride film. The back gate separation pattern 111 may be formed at the same level as the gate capping pattern 143, which will be described below. Here, the “same level” means formation by the same fabricating process. The back gate separation pattern 111 may be formed of the same material as the gate capping pattern 143.

A back gate insulating pattern 113 may be disposed between the back gate electrode BG and the first active pattern AP1, and between the back gate electrode BG and the second active pattern AP2. The back gate insulating pattern 113 may be disposed between the back gate separation pattern 111 and the first active pattern AP1, and between the back gate separation pattern 111 and the second active pattern AP2. The back gate insulating pattern 113 may include, for example, a silicon oxide film, a silicon oxynitride film, a high dielectric constant insulating film having a dielectric constant higher than that of the silicon oxide film, or combinations thereof.

The back gate capping pattern 115 may be disposed between the bit line BL and the back gate electrode BG. The back gate capping pattern 115 may be disposed between the first active pattern AP1 and the second active pattern AP2 adjacent to each other in the second direction D2. The back gate capping pattern 115 may extend in the first direction D1 along with the back gate electrode BG. The back gate capping pattern 115 may be disposed on the first face BG_S1 of the back gate electrode.

The back gate capping pattern 115 may be made of an insulating material. The back gate capping pattern 115 may include, for example, at least one of a silicon oxide film, a silicon oxynitride film, and a silicon nitride film.

The back gate contact plug BGPL may be disposed between the back gate strap line BG_SL and the back gate electrodes BG. The back gate contact plug BGPL connects the back gate strap line BG_SL and the back gate electrodes BG. The back gate contact plug BGPL may be disposed between the first dummy active pattern APD1 and the second dummy active pattern APD2 that are adjacent in the second direction D2.

The back gate contact plug BGPL may be connected to the first face BG_S1 of the back gate electrode. The back gate contact plug BGPL may pass through the back gate capping pattern 115 and be connected to the back gate electrode BG.

The back gate contact plug BGPL may include a first face BGPL_S1 and a second face BGPL_S2 that are opposite to each other in the third direction D3. The first face BGPL_S1 of the back gate contact plug may be connected to the back gate strap line BG_SL. The second face BGPL_S2 of the back gate contact plug may be connected to the back gate electrode BG.

The width of the back gate contact plug BGPL may decrease as it goes away from the back gate strap line BG_SL. For example, a width W21 of the first face BGPL_S1 of the back gate contact plug is greater than a width W22 of the second face BGPL_S2 of the back gate contact plug. Although not shown, when the back gate contact plug BGPL is cut in the first direction D1, the width of the back gate contact plug BGPL may decrease as it goes away from the back gate strap line BG_SL.

The back gate contact plug BGPL includes a conductive material, and may include, for example, at least one of a conductive semiconductor material, conductive metal nitride, conductive metal silicon nitride, metal carbonitride, conductive metal silicide, conductive metal oxide, a two-dimensional dimensional material, and a metal.

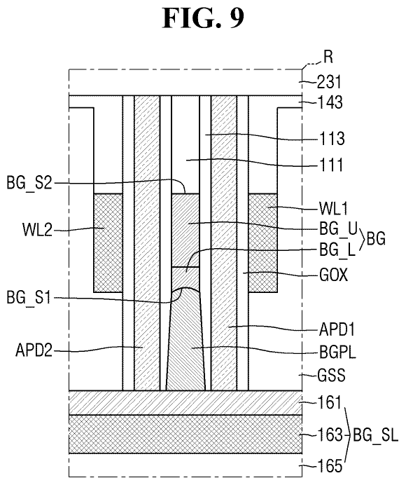

In FIGS. 8 and 9, the back gate strap line BG_SL may include a semiconductor pattern 161 and a metal pattern 163. As an example, the back gate contact plug BGPL may include a conductive semiconductor material. As another example, the back gate contact plug BGPL may include a metal.

In FIG. 8, as an example, the back gate electrode BG may include a conductive semiconductor material. As another example, the back gate electrode BG may include a metal.

In FIG. 9, the back gate electrode BG may include an upper back gate electrode BG_U and a lower back gate electrode BG_L. The upper back gate electrode BG_U may include, for example, a metal. The lower back gate electrode BG_L may include a conductive semiconductor material.

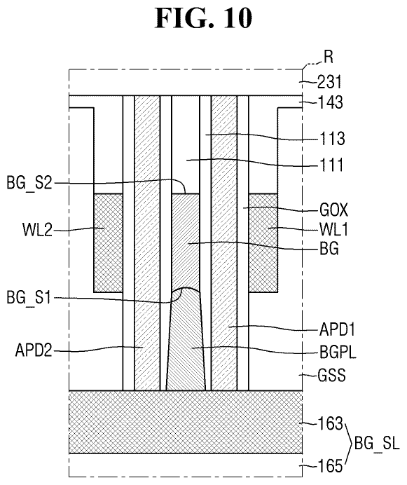

In FIG. 10, the back gate strap line BG_SL may include a metal pattern 163 without a semiconductor pattern 161. For example, the back gate contact plug BGPL may include a metal. As an example, the back gate electrode BG may include a conductive semiconductor material. As another example, the back gate electrode BG may include a metal.

The materials for the back gate electrode BG, the back gate strap line BG_SL, and the back gate contact plug BGPL described above are only examples, and technical ideas of the present disclosure are not limited thereto.

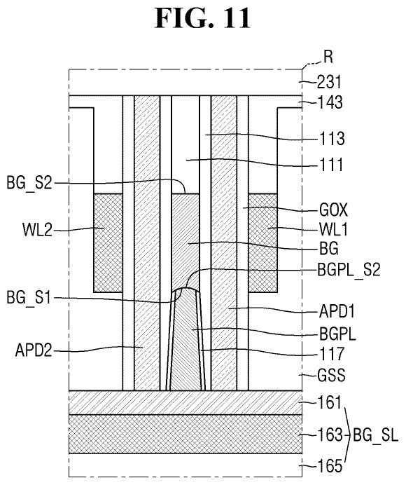

In FIG. 11, the plug spacer 117 may be disposed on a side wall of the back gate contact plug BGPL. The side wall of the back gate contact plug BGPL connects the first face BGPL_S1 of the back gate contact plug and the second face BGPL_S2 of the back gate contact plug. The plug spacer 117 includes an insulating material.

In the semiconductor memory device according to some embodiments, the back gate strap line BG_SL may be connected to the entire back gate electrodes BG disposed in the cell array region CAR.

In FIG. 12, the back gate electrodes BG may include a first back gate electrode BG_1 and a second back gate electrode BG_2 alternately disposed in the second direction D2. The first back gate electrode BG_1 and the second back gate electrode BG_2 may be connected to one back gate strap line BG_SL. The first back gate electrode BG_1 may be connected to the back gate strap line BG_SL through the back gate contact plug BGPL. The second back gate electrode BG_2 may be connected to the back gate strap line BG_SL through the back gate contact plug BGPL.

Although one back gate strap line BG_SL connected to the back gate electrode BG is shown, the embodiment is not limited thereto. Unlike the shown example, a plurality of back gate strap lines BG_SL may be disposed at the boundary of on both sides of the cell array region CAR. In such a case, each back gate strap line BG_SL may be connected to the entire back gate electrodes BG disposed in the cell array region CAR.

Since the back gate strap line BG_SL formed at the same time as the bit line BL is connected to the back gate electrode BG, an additional wiring process for connection with the back gate electrode BG is not required. This makes it possible to simplify and facilitate the fabricating process.

In addition, there is no need for an additional space for forming a wiring for connection with the back gate electrode BG. As a result, the wiring may be efficiently disposed in the boundary portion between the cell array region CAR and the peripheral circuit region PCR.

The first word line WL1 and the second word line WL2 may be disposed on the bit line BL and the shielding conductive pattern SL. The first word line WL1 and the second word line WL2 may be disposed on the shielding conductive protruding pattern SLp. The first word line WL1 and the second word line WL2 may be disposed on the back gate strap line BG_SL and the dummy bit line BL_D.

Each of the first word line WL1 and the second word line WL2 may extend in the first direction D1. The first word line WL1 and the second word line WL2 may be alternately arranged in the second direction D2.

The first word line WL1 may be disposed on the second side walls SS2 of the first active patterns AP1. The second word line WL2 may be disposed on the first side walls SS1 of the second active patterns AP2. The first active patterns AP1 and the second active patterns AP2 may be disposed between the first word line WL1 and the second word line WL2 adjacent in the second direction D2. The first dummy active pattern APD1 and the second dummy active pattern APD2 may be disposed between the first word line WL1 and the second word line WL2 adjacent in the second direction D2.

The first word line WL1 and the second word line WL2 may be spaced apart from the bit line BL and the contact pattern BC in the third direction D3. The first word line WL1 and the second word line WL2 may be positioned between the bit line BL and the contact pattern BC.

Each of the first word line WL1 and the second word line WL2 may have a width in the second direction D2. The width of the first word line WL1 and the width of the second word line WL2 on the bit line BL may differ from the width of the first word line WL1 and the width of the second word line WL2 on the shielding conductive pattern SL.

For example, each of the first word line WL1 and the second word line WL2 may include a first portion WLa of the word line, and a second portion WLb of the word line. The width of the first portion WLa of the word line in the second direction D2 may be smaller than the width of the second portion WLb of the word line in the second direction D2. As an example, the first portion WLa of the word line may overlap the bit line BL in the third direction D3. The second portion WLb of the word line may overlap the shielding conductive line SL in the third direction D3.

Each of the first word line WL1 and the second word line WL2 may include a first portion WLa of the word line and a second portion WLb of the word line that are alternately arranged along the first direction D1. In the first word line WL1, each first active pattern AP1 may be disposed between the second portions WLb of the word line adjacent in the first direction D1. In the second word lines WL2, each second active pattern AP2 may be disposed between the second portions WLb of the word line adjacent in the first direction D1.

The first word line WL1 and the second word line WL2 may include a first face WL_S1 and a second face WL_S2 that are opposite to each other in the third direction D3. The first face WL_S1 of the first and second word lines WL1 and WL2 is closer to the bit line BL than the second face WL_S2 of the first and second word lines WL1 and WL2.

The first word line WL1 will be described as an example. As an example, a height of the first word line WL1 in the third direction D3 may be equal to a height of the back gate electrode BG in the third direction D3. As another example, the height of the first word line WL1 in the third direction D3 may be greater than the height of the back gate electrode BG in the third direction D3. As still another example, the height of the first word line WL1 in the third direction D3 may be smaller than the height of the back gate electrode BG in the third direction D3.

Further, as an example, the height of the first face WL_S1 of the first word line may be equal to the height of the first face BG_S1 of the back gate electrode, on the basis of the bit line BL. As another example, the first face WL_S1 of the first word line may be higher than the first face BG_S1 of the back gate electrode. As yet another example, the first face WL_S1 of the first word line may be lower than the first face BG_S1 of the back gate electrode.

In addition, as an example, the height of the second face WL_S2 of the first word line may be equal to the height of the second face BG_S2 of the back gate electrode, on the basis of the bit line BL. As another example, the second face WL_S2 of the first word line may be higher than the second face BG_S2 of the back gate electrode. As yet another example, the second face WL_S2 of the first word line may be lower than the second face BG_S2 of the back gate electrode.

The first word line WL1 and the second word line WL2 include a conductive material. The first word line WL1 and the second word line WL2 may include, for example, at least one of a conductive semiconductor material, conductive metal nitride, conductive metal silicon nitride, metal carbonitride, conductive metal silicide, conductive metal oxide, a two-dimensional material, and a metal. Although the first word line WL1 and the second word line WL2 are shown as being a single conductive film, this is only for convenience of explanation, and the embodiment is not limited thereto.

The first faces WL_S1 of the first and second word lines WL1 and WL2 may be a plane. Unlike the shown example, as an example, the first faces WL_S1 of the first and second word lines WL1 and WL2 may be concavely rounded. As another example, each of the first word line WL1 and the second word line WL2 may have the form of spacers. In other words, the first faces WL_S1 of the first and second word lines WL1 and WL2 may be convexly rounded.

The second face WL_S2 of the first and second word lines WL1 and WL2 may be a plane. Unlike the shown example, the second faces WL_S2 of the first and second word lines WL1 and WL2 may have concave curved faces. The first face BG_S1 of the back gate electrode and the second face BG_S2 of the back gate electrode are shown as a plane, but the embodiment is not limited thereto.

A dummy word line WL_D may extend along the boundary of the cell array region CAR. The dummy word line WL_D may extend along the cell region element separation film STI. The dummy word line WL_D may extend in the first direction D1. The dummy word line WL_D may be spaced apart from the first and second word lines WL1 and WL2 in the second direction D2.

The boundary dummy active patterns APD_E may be disposed between the dummy word line WL_D and the cell region element separation film STI. The dummy word line WL_D may be similar in shape to the first word line WL1 and the second word line WL2. The dummy word line WL_D may be formed at the same level as the first and second word lines WL1 and WL2.

Gate insulating patterns GOX may be disposed between the first word line WL1 and the first active pattern AP1, and between the second word line WL2 and the second active pattern AP2. The gate insulating patterns GOX may be disposed between the first word line WL1 and the first dummy active pattern APD1, and between the second word line WL2 and the second dummy active pattern APD2. The gate insulating pattern GOX may extend in the first direction D1 along with the first word line WL1 and the second word line WL2. The gate insulating patterns GOX may be disposed between the dummy word line WL_D and a boundary dummy active pattern APD_E.

The gate insulating pattern GOX may include a silicon oxide film, a silicon oxynitride film, a high dielectric constant insulating film having a dielectric constant higher than that of the silicon oxide film, or a combination thereof.

The gate insulating pattern GOX may extend along the second side wall SS2 of the first active pattern AP1, and may extend along the first side wall SS1 of the second active pattern AP2. In the semiconductor memory device according to some embodiments, the gate insulating pattern GOX between the first active pattern AP1 and the first word line WL1 may be separated from the gate insulating pattern GOX between the second active pattern AP2 and the second word line WL2 from the viewpoint of a cross-sectional view.

The gate capping pattern 143 may be disposed between the first word line WL1 and the contact pattern BC, and between the second word line WL2 and the contact pattern BC. The gate capping pattern 143 may cover the second faces WL_S2 of the first and second word lines WL1 and WL2.

A gate separation pattern GSS may be disposed on the bit line BL. The gate separation pattern GSS may be disposed on the bit line BL, and may be disposed on the back gate strap line BG_SL and the dummy bit line BL_D. The gate separation pattern GSS may be disposed between the bit line BL and the contact pattern BC. The gate separation pattern GSS may be in contact with the bit line BL.

The gate separation pattern GSS may be disposed between the first word line WL1 and the second word line WL2 adjacent to each other in the second direction D2. The first word line WL1 and the second word line WL2 may be separated by the gate separation pattern GSS. The gate separation pattern GSS may extend in the first direction D1 between the first word line WL1 and the second word line WL2.

The first word line WL1 may be disposed between the gate separation pattern GSS and the first active pattern AP1. The second word line WL2 may be disposed between the gate separation pattern GSS and the second active pattern AP2.

The gate separation pattern GSS may include a horizontal part GSS_H and a protruding part GSS_P. The protruding part GSS_P of the gate separation pattern may protrude from the horizontal part GSS_H of the gate separation pattern in the third direction D3.

The horizontal part GSS_H of the gate separation pattern may be closer to the bit line BL than the protruding part GSS_P of the gate separation pattern. The horizontal part GSS_H of the gate separation pattern may be in contact with the bit line BL. A width of the horizontal part GSS_H of the gate separation pattern in the second direction D2 is greater than a width of the protruding part GSS_P of the gate separation pattern in the second direction D2.

The protruding part GSS_P of the gate separation pattern may be disposed between the side walls of the first word line WL1 and the side walls of the second word line WL2 that face each other. The horizontal part GSS_H of the gate separation pattern may cover the first faces WL_S1 of the first and second word lines WL1 and WL2.

The first word line WL1 and the second word line WL2 are disposed on the horizontal part GSS_H of the gate separation pattern. The first word line WL1 and the second word line WL2 may have a shape that gets on the horizontal part GSS_H of the gate separation pattern. The first word line WL1 and the second word line WL2 may be disposed between the horizontal part GSS_H of the gate separation pattern and the contact pattern BC.

The gate separation pattern GSS may be made of an insulating material. The gate separation pattern GSS may include a plurality of insulating films, unlike the shown example.

The contact patterns BC may pass through the contact interlayer insulating film 231. The contact patterns BC may be connected to each of the first active pattern AP1 and the second active pattern AP2. The contact patterns BC may be connected to the second faces S2 of the first and second active patterns AP1 and AP2. Each contact pattern BC may have various shapes such as a circle, an ellipse, a rectangle, a square, a rhombus, and a hexagon from the viewpoint of a plan view. The contact interlayer insulating film 231 may be disposed on the cell region element separation film STI.

The contact pattern BC may include a conductive material. The contact pattern BC may include, for example, at least one of a conductive semiconductor material, conductive metal nitride, conductive metal silicon nitride, metal carbonitride, conductive metal silicide, conductive metal oxide, a two-dimensional material, and a metal. The contact interlayer insulating film 231 includes an insulating material.

Landing pads LP may be disposed on the contact pattern BC. The landing pads LP may have various shapes such as a circle, an ellipse, a rectangle, a square, a rhombus, and a hexagon from the viewpoint of a plan view.

The pad separation insulating film 245 may be disposed on the contact interlayer insulating film 231. The pad separation insulating film 245 may be disposed between the landing pads LP. The pad separation insulating film 245 may separate the landing pads LP. From the viewpoint of a plan view, the landing pads LP may be arranged in the form of a matrix along the first direction D1 and the second direction D2. The upper face of the landing pad LP may be substantially coplanar with the upper face of the pad separation insulating film 245.

The landing pad LP includes a conductive material, and may include, for example, at least one of a conductive semiconductor material, conductive metal nitride, conductive metal silicon nitride, metal carbonitride, conductive metal silicide, conductive metal oxide, a two-dimensional material, and a metal. The pad separation insulating film 245 includes an insulating material.

A word line contact plug 281a may be connected to the word lines WL1 and WL2. A word line contact plug 281a may be disposed in the contact interlayer insulating film 231 and the gate separation pattern GSS. The word line contact plug 281a may be connected to the second face WL_S2 of the first and second word lines WL1 and WL2.

A bit line contact plug 281b may be connected to the bit line BL. The bit line contact plugs 281b may be disposed in the contact interlayer insulating film 231 and the cell region element separation film STI. The bit line contact plug 281b is connected to a conductive bit line.

A strap line contact plug 281c may be connected to the back gate strap line BG_SL. The strap line contact plug 281c may be disposed in the contact interlayer insulating film 231 and the cell region element separation film STI. The strap line contact plug 281c is connected to the conductive strap line.

The first to third upper connection wirings 282a, 282b and 282c may be disposed inside the pad separation insulating film 245. The first upper connection wiring 282a may be connected to the word line contact plug 281a. The second upper connection wiring 282b may be connected to the bit line contact plug 281b. The third upper connection wiring 282c may be connected to the strap line contact plug 281c.

The first to third upper peripheral contact plugs 283a, 283b and 283c may be connected to the peri-connection wiring 242b. The first to third upper peripheral contact plugs 283a, 283b and 283c may pass through the contact interlayer insulating film 231, the cell region element separation film STI and the first upper insulating film 263.

The first upper peripheral contact plug 283a may connect the first and second word lines WL1 and WL2 and the peri-connection wiring 242b. The second upper peripheral contact plug 283b may connect the bit line BL and the peri-connection wiring 242b. The third upper peripheral contact plug 283c may connect the back gate strap line BG_SL and the peri-connection wiring 242b.

The word line contact plug 281a, the bit line contact plug 281b, the strap line contact plug 281c, the first to third upper connection wirings 282a, 282b and 282c and the first to third upper peripheral contact plugs 283a, 283b and 283c each include a conductive material.

The data storage patterns DSP may each be disposed on the landing pads LP. The data storage patterns DSP may be electrically connected to the first and second active patterns AP1 and AP2, respectively. The data storage patterns DSP may be arranged in the form of a matrix along the first direction D1 and the second direction D2, as shown in FIG. 2. The data storage patterns DSP may completely or partially overlap the landing pad LP in the third direction D3. The data storage patterns DSP may be in contact with all or part of the upper face of the landing pad LP.

As an example, the data storage patterns DSP may be a capacitor. The data storage patterns DSP may include a capacitor dielectric film 253 interposed between the storage electrodes 251 and the plate electrode 255. The storage electrode 251 may be in contact with the landing pad LP. The storage electrode 251 may have various shapes such as a circle, an ellipse, a rectangle, a square, a rhombus, and a hexagon from the viewpoint of a plan view. The storage electrodes 251 may pass through the upper etching stop film 247. The upper etching stop film 247 may be disposed on the pad separation insulating pattern 245. The upper etching stop film 247 may be made of an insulating material.

The plate electrode 255 may include a lower plate electrode 255a and an upper plate electrode 255b. The plate electrode 255 may be a single film, unlike the shown example. The storage electrode 251 and the plate electrode 255 may each made include, for example, at least one of a conductive semiconductor material, conductive metal nitride, conductive metal silicon nitride, metal carbonitride, conductive metal silicide, conductive metal oxide, and a metal. The capacitor dielectric film 253 may include at least one of a ferroelectric material, an antiferroelectric material, and a paraelectric material. For example, the capacitor dielectric film 253 may include the ferroelectric material, the antiferroelectric material, the paraelectric material, a combination of the ferroelectric material and the antiferroelectric material, a combination of the ferroelectric material and the paraelectric material, a combination of the paraelectric material and the antiferroelectric material, and a combination of the ferroelectric material, the antiferroelectric material and the paraelectric material.

In contrast, the data storage patterns DSP may be a variable resistance pattern that may be switched between two resistance statuses by electrical pulses applied to the memory elements. For example, the data storage patterns DSP may include a phase-change material in which a crystal status changes depending on the amount of current, perovskite compounds, transition metal oxide, magnetic materials, ferromagnetic materials or antiferromagnetic materials.

A second upper insulating film 271 may be disposed on the upper etching stop film 247. The second upper insulating film 271 may be disposed on the data storage pattern DSP. For example, the second upper insulating film 271 may cover the data storage pattern DSP. The second upper insulating film 271 may wrap the side walls of the plate electrode 255. The second upper insulating film 271 includes an insulating material.

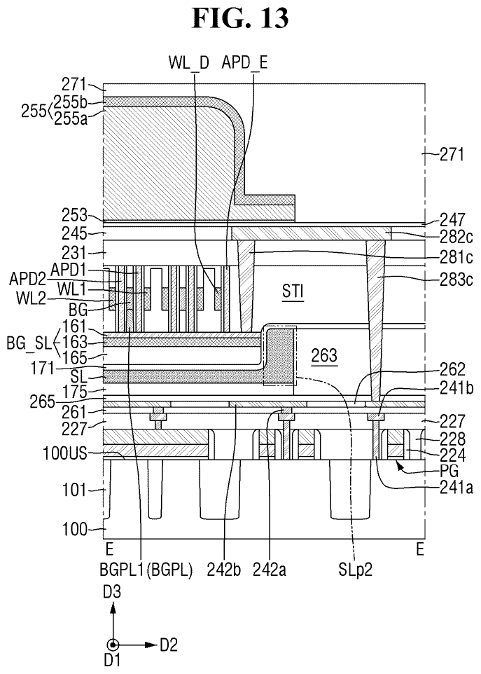

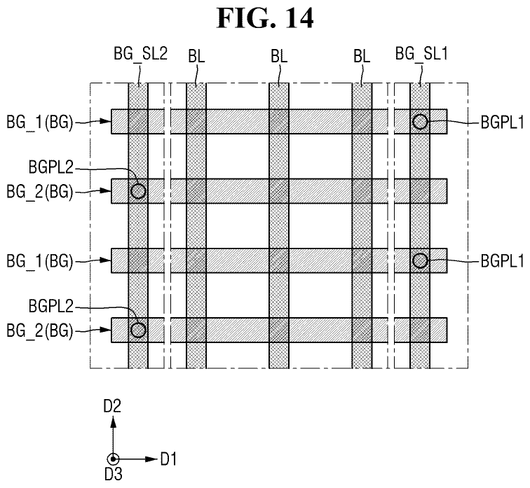

FIGS. 13 and 14 are diagrams for explaining a semiconductor memory device according to some embodiments. For convenience of explanation, the explanation will focus on points that are different from those explained using FIGS. 1 to 12.

For reference, FIG. 13 is a cross-sectional view taken along a portion E-E of FIG. 2. FIG. 14 is an example diagram for explaining a shape in which the back gate electrodes and the back gate strap line are connected in the cell array region.

Referring to FIGS. 13 and 14, the semiconductor memory device according to some embodiments may include a first back gate strap line BG_SL1 and a second back gate strap line BG_SL2.

The first back gate strap line BG_SL1 and the second back gate strap line BG_SL2 are connected in the second direction D2. The bit lines BL are disposed between the first back gate strap line BG_SL1 and the second back gate strap line BG_SL2.

The first back gate strap line BG_SL1 may be connected to a part of the back gate electrodes BG. The second back gate strap line BG_SL2 may be connected to the rest of the back gate electrodes BG.

The back gate electrode BG may include a first back gate electrode BG_1 and a second back gate electrode BG_2 that are alternately disposed in the second direction D2. For example, the first back gate strap line BG_SL1 may be connected to the first back gate electrode BG_1. The second back gate strap line BG_SL2 may be connected to the second back gate electrode BG_2.

The first back gate electrode BG_1 may be connected to the first back gate strap line BG_SL1 through a first back gate contact plug BGPL1. The second back gate electrode BG_2 may be connected to the second back gate strap line BG_SL2 through a second back gate contact plug BGPL2. The first back gate contact plug BGPL1 and the second back gate contact plug BGPL2 may be disposed in zigzag along the boundary of the cell array region CAR.

The description of the first back gate strap line BG_SL1 and the second back gate strap line BG_SL2 is substantially the same as that of the back gate strap line BG_SL described using FIGS. 1 to 12.

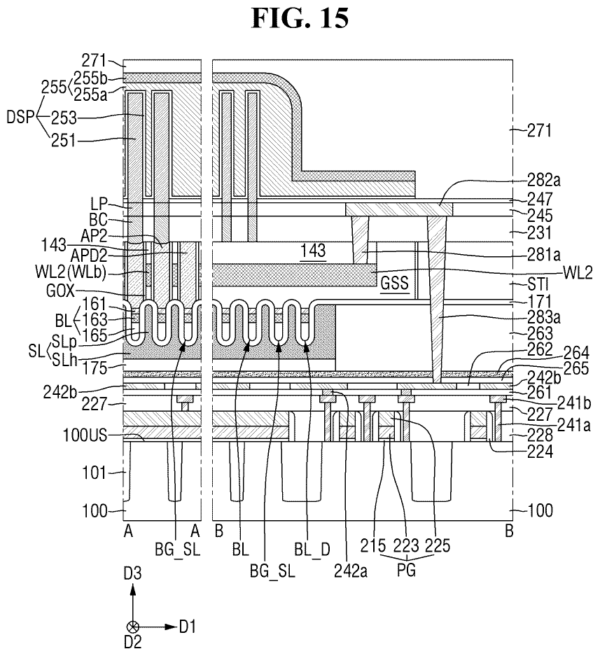

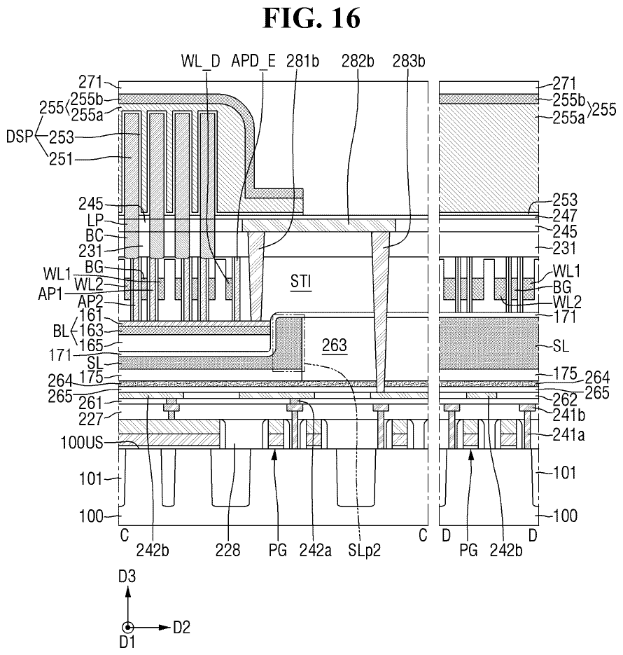

FIGS. 15 and 16 are diagrams for explaining a semiconductor memory device according to some embodiments. For convenience of explanation, the explanation will focus on points that are different from those explained using FIGS. 1 to 12.

Referring to FIGS. 15 and 16, the semiconductor memory device according to some embodiments may further include a bonding insulating film 264 interposed between the peri-connection structures 242a and 242b and the first upper insulating film 263.

For example, the bonding insulating film 264 may be disposed between the first upper insulating film 263 and the third peri-upper insulating film 265, and between the shielding insulation capping film 175 and the third peri-upper insulating film 265. The bonding insulating film 264 may include, for example, silicon carbonitride (SiCN).

Unlike the shown example, the third peri-upper insulating film 265 may not be disposed on the peri-connection wiring 242b.

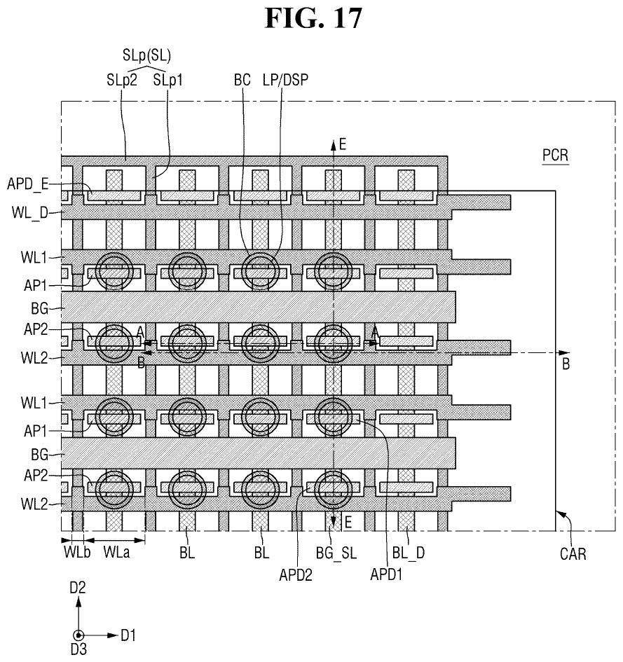

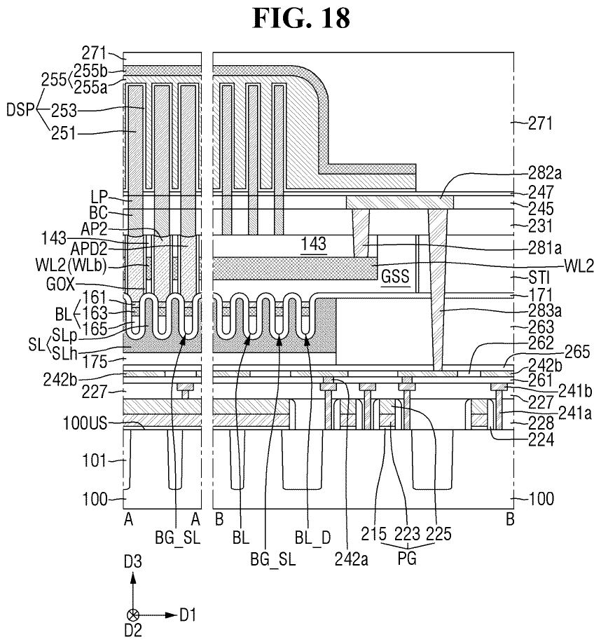

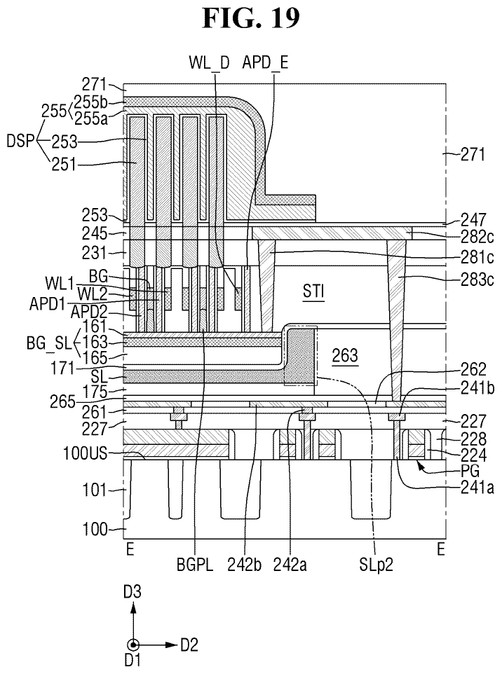

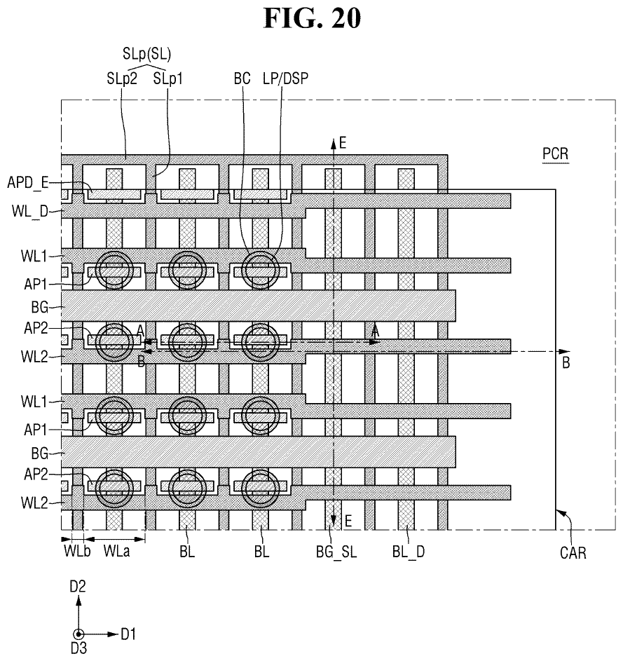

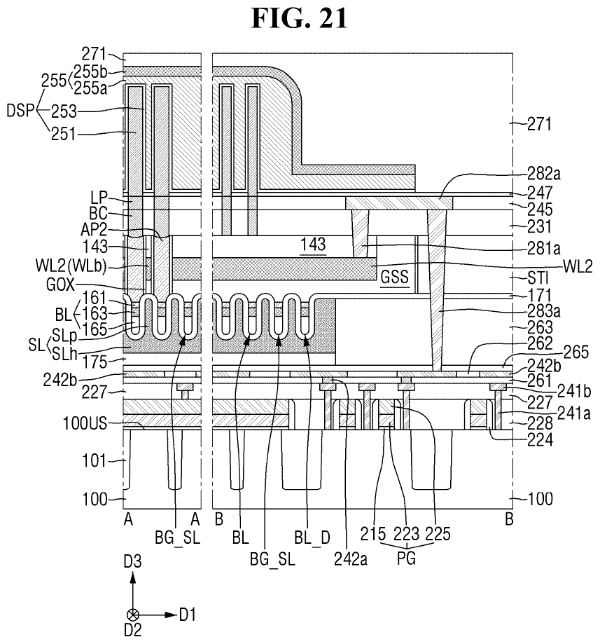

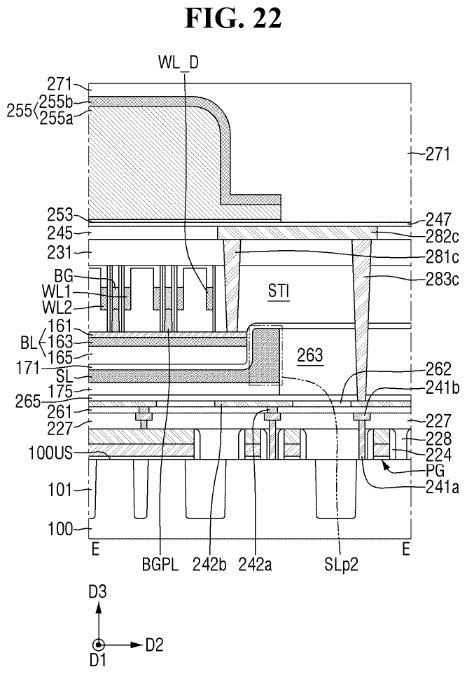

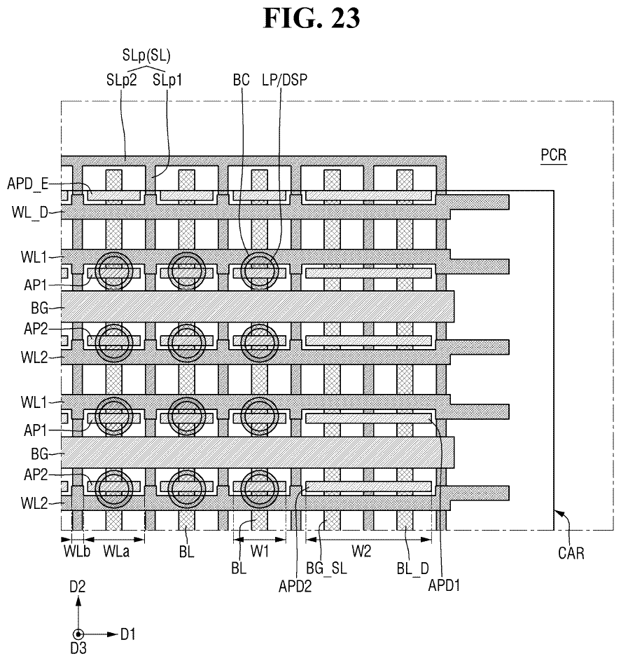

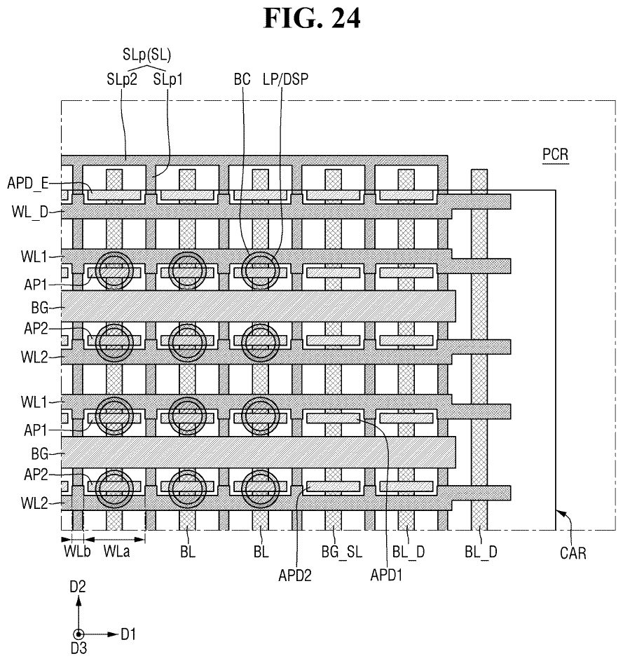

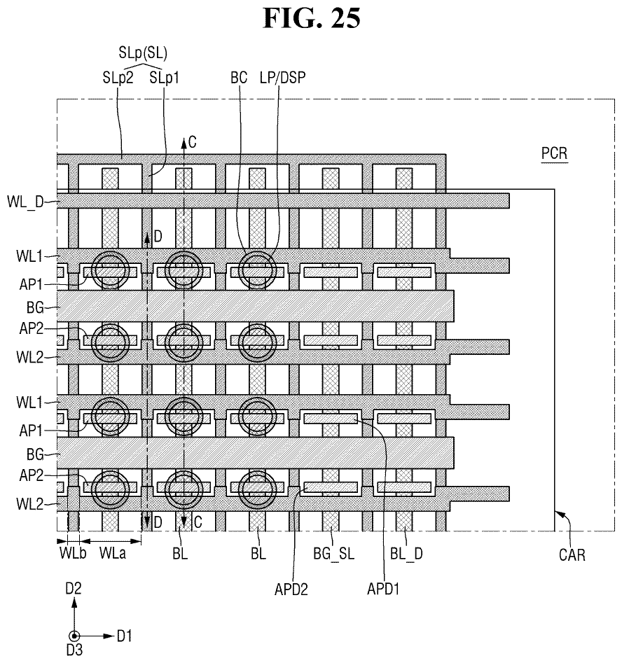

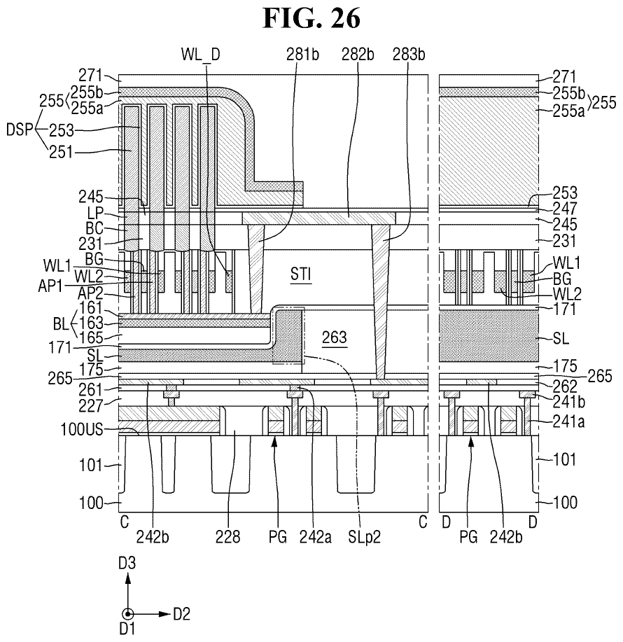

FIGS. 17 to 19 are diagrams for explaining a semiconductor memory device according to some embodiments. FIGS. 20 to 22 are diagrams for explaining the semiconductor memory device according to some embodiments. FIGS. 23 and 24 are diagrams for explaining the semiconductor memory device according to some embodiments, respectively. FIGS. 25 and 26 are diagrams for explaining the semiconductor memory device according to some embodiments. For convenience of explanation, the explanation will focus on points that are different from those explained using FIGS. 1 to 12.

Referring to FIGS. 17 to 19, in the semiconductor memory device according to some embodiments, the first dummy active pattern APD1 and the second dummy active pattern APD2 connected to the back gate strap line BG_SL may be connected to the data storage pattern DSP.

Unlike the shown example, the first dummy active pattern APD1 and the second dummy active pattern APD2 connected to the dummy bit line BL may be connected to the data storage pattern DSP.

A plurality of dummy bit lines BL may be disposed unlike the shown example. A first dummy active pattern APD1 and a second dummy active pattern APD2 connected to a part of the plurality of dummy bit lines BL_D may be connected to the data storage pattern DSP. The first dummy active pattern APD1 and the second dummy active pattern APD2 connected to the rest of the plurality of dummy bit lines BL_D may not be connected to the data storage pattern DSP.

Referring to FIGS. 20 to 22, in the semiconductor memory device according to some embodiments, the first dummy active pattern APD1 and the second dummy active pattern APD2 may not be disposed on the back gate strap line BG_SL.

The first dummy active pattern APD1 and the second dummy active pattern APD2 may not be disposed on the dummy bit line BL_D. The boundary dummy active pattern APD_E may not be disposed on the back gate strap line BG_SL and the dummy bit line BL_D.

Unlike the shown example, the first dummy active pattern APD1, the second dummy active pattern APD2, and the boundary dummy active pattern APD_E may be disposed on the back gate strap line BG_SL. The first dummy active pattern APD1, the second dummy active pattern APD2, and the boundary dummy active pattern APD_E may not be disposed on the dummy bit line BL_D.

Referring to FIG. 23, in the semiconductor memory device according to some embodiments, the first dummy active pattern APD1 and the second dummy active pattern APD2 alternately disposed in the second direction D2 may be disposed on the back gate strap lines BG_SL and the dummy bit line BL_D.

The first dummy active pattern APD1 and the second dummy active pattern APD2 alternately disposed in the second direction D2 may be in contact with the back gate strap line BG_SL and the dummy bit line BL_D. For example, one first dummy active pattern APD1 may be in contact with the back gate strap line BG_SL and the dummy bit line BL_D. One second dummy active pattern APD2 may be in contact with the back gate strap line BG_SL and the dummy bit line BL_D.

The lengths of the first and second dummy active patterns APD1 and APD2 may be longer than the lengths of the first and second active patterns AP1 and AP2. The second active pattern AP2 and the second dummy active pattern APD2 will be described as an example. A length W1 in the first direction D1 of the second active pattern AP2 connected to the bit line BL may be smaller than a length W2 in the first direction D1 of the second dummy active pattern APD2 connected to the back gate strap line BG_SL.

Referring to FIG. 24, in the semiconductor memory device according to some embodiments, at least one of the dummy bit lines BL_D does not overlap the back gate electrodes BG in the third direction D3.

From the viewpoint of a plan view, at least one of the dummy bit lines BL_D does not intersect the back gate electrode BG. For example, the dummy bit line BL_D that does not intersect the back gate electrode BG may intersect the first word line WL1 and the second word line WL2.

Referring to FIGS. 25 and 26, in the semiconductor memory device according to some embodiments, the boundary dummy active patterns (APD_E of FIG. 2) are not disposed along the boundary of the cell array region CAR.

The dummy word line WL_D may extend along the boundary of the cell array region CAR, that is, along the side wall of the cell region element separation film STI. The dummy word line WL_D may not be disposed along the boundary of cell array region CAR, unlike the shown example.

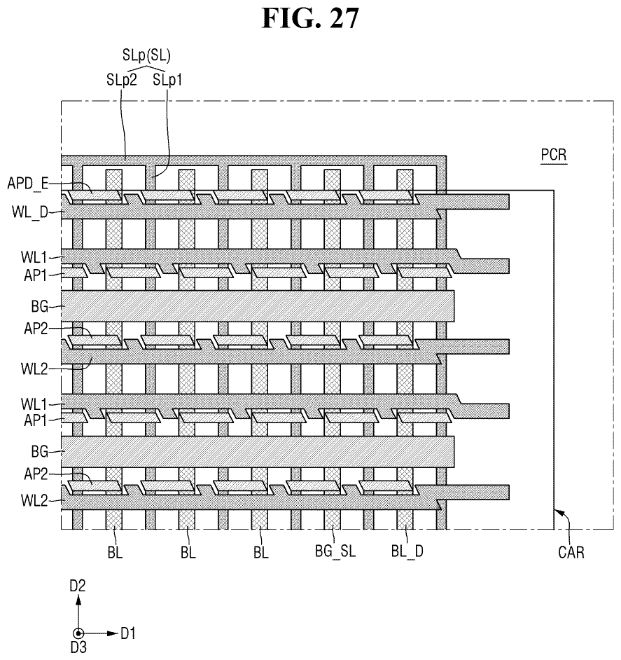

FIGS. 27 to 30 are diagrams for explaining a semiconductor memory device according to some embodiments. For convenience of explanation, the explanation will focus on points that are different from those explained using FIGS. 1 to 26.

Referring to FIG. 27, in the semiconductor memory device according to some embodiments, the first and second active patterns AP1 and AP2 may be alternately arranged in an oblique direction with respect to the first direction D1 and the second direction D2.

From the viewpoint of a plan view, each of the first and second active patterns AP1 and AP2 may have a parallelogram or rhombus shape. Since the first and second active patterns AP1 and AP2 are disposed in the oblique direction, coupling between the first and second active patterns AP1 and AP2 facing in the second direction D2 may be reduced.

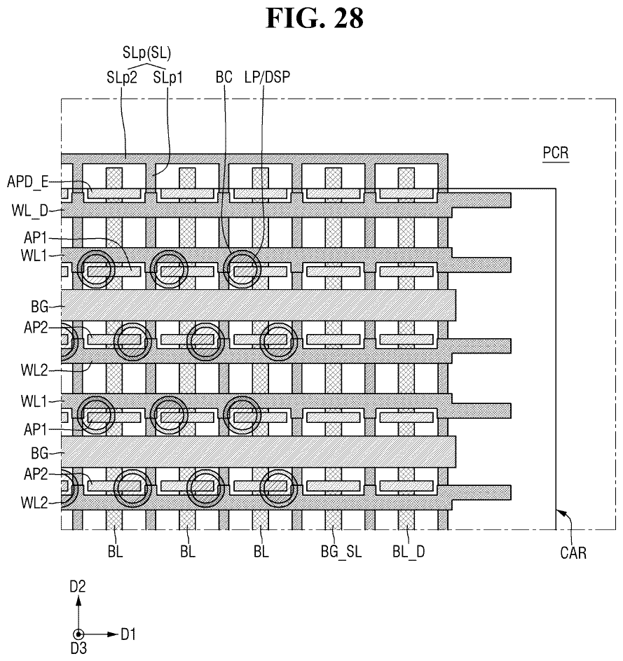

Referring to FIG. 28, in the semiconductor memory device according to some embodiments, landing pads LP and data storage patterns DSP may be arranged in a zigzag or honeycomb form from the viewpoint of a plan view.

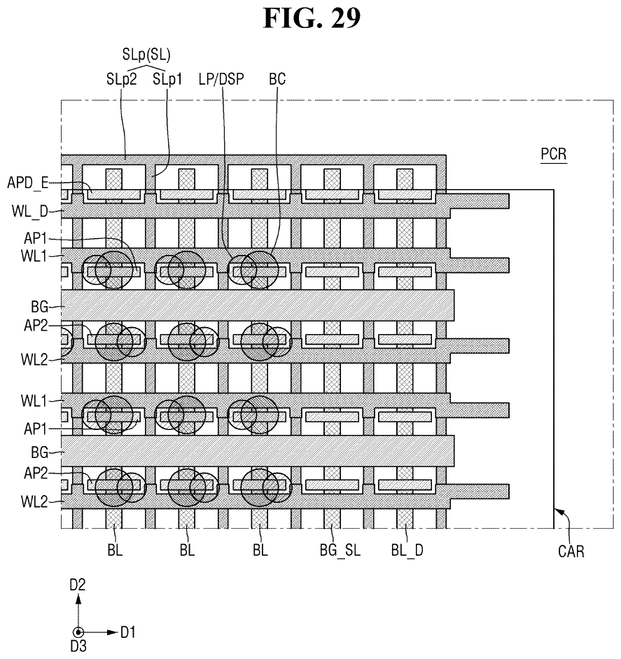

Referring to FIG. 29, in the semiconductor memory device according to some embodiments, the data storage patterns DSP may be disposed to deviate from the landing pads LP from the viewpoint of a plan view.

Each data storage pattern DSP may be in contact with a part of the landing pad LP.

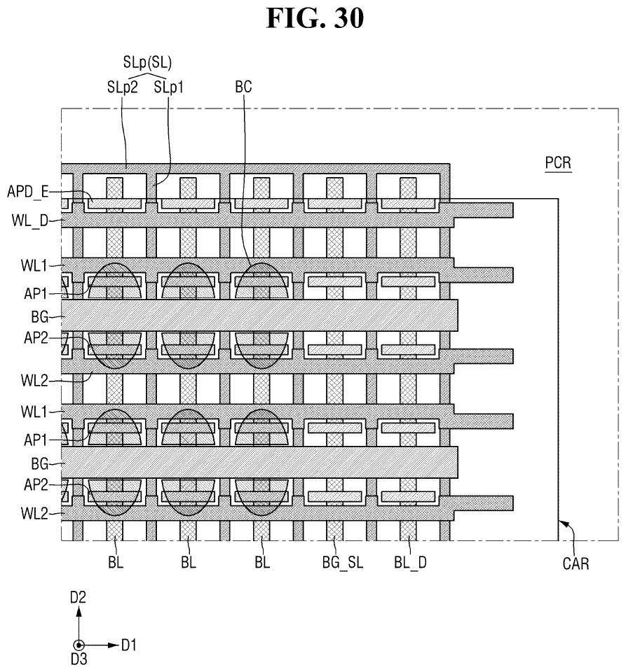

Referring to FIG. 30, in the semiconductor memory device according to some embodiments, each of the contact patterns BC disposed on the first and second active patterns AP1 and AP2 may have a semi-circular or semi-oval form from the viewpoint of a plan view.

The contact patterns BC may be disposed symmetrically with respect to each other with the back gate electrode BG interposed therebetween from the viewpoint of a plan view.

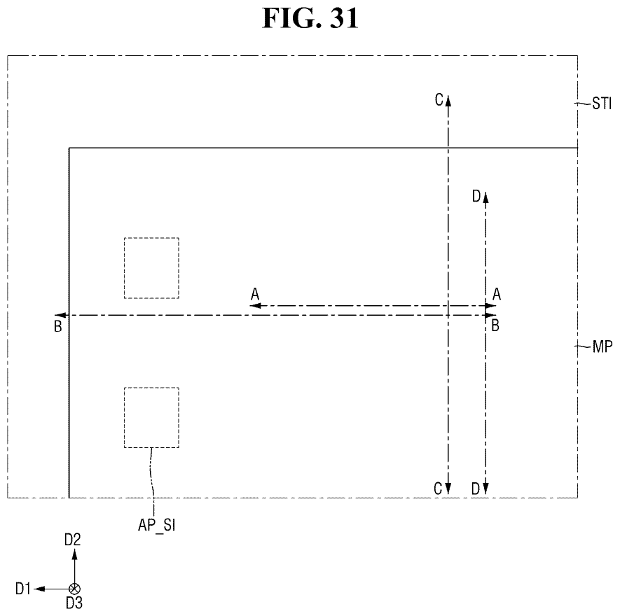

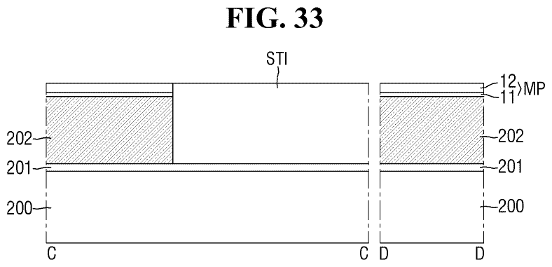

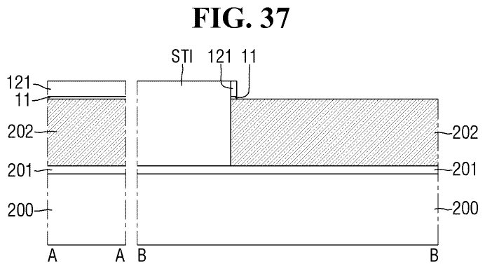

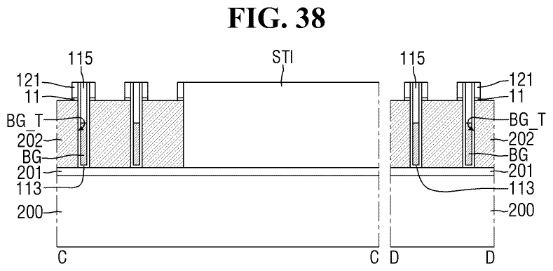

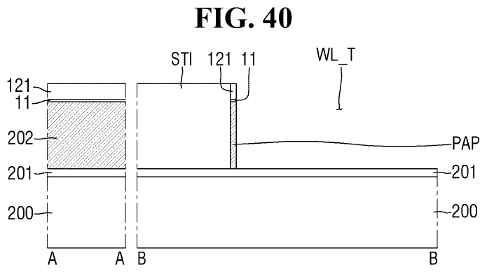

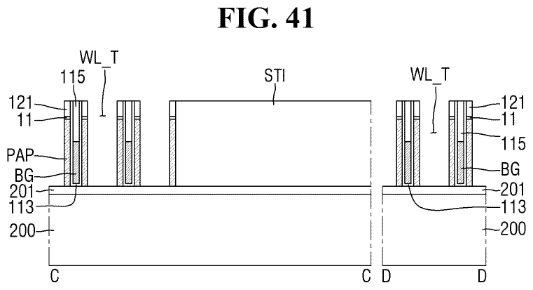

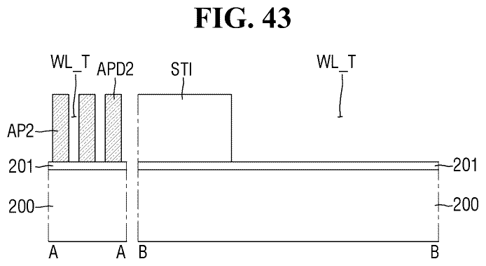

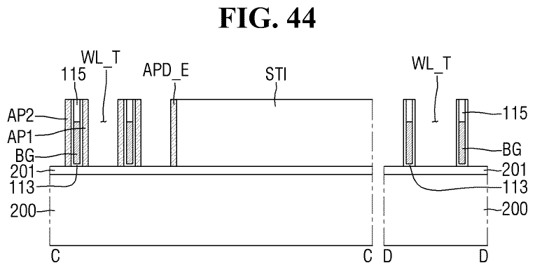

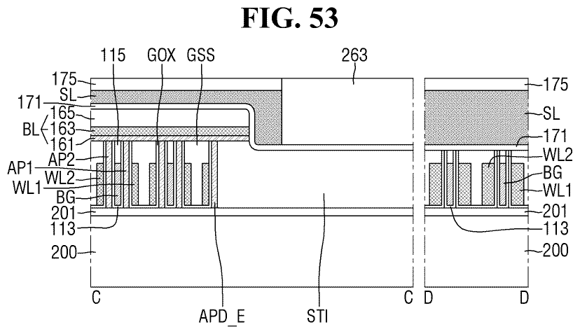

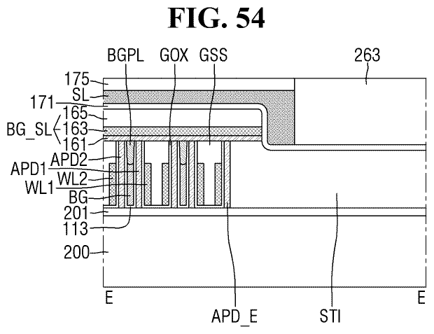

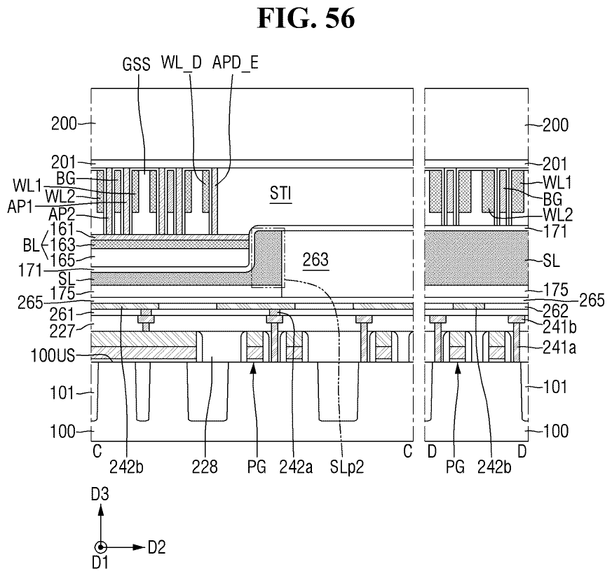

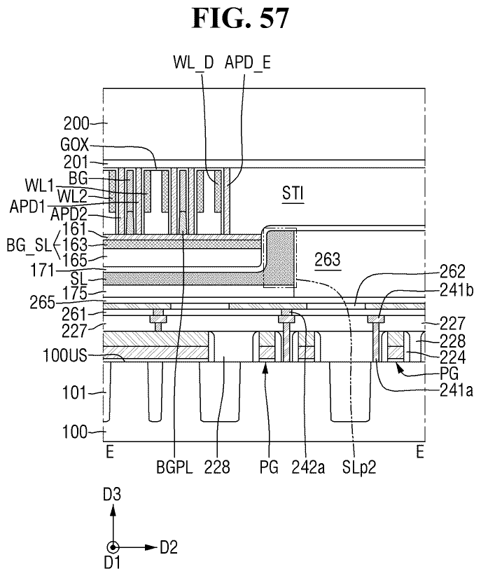

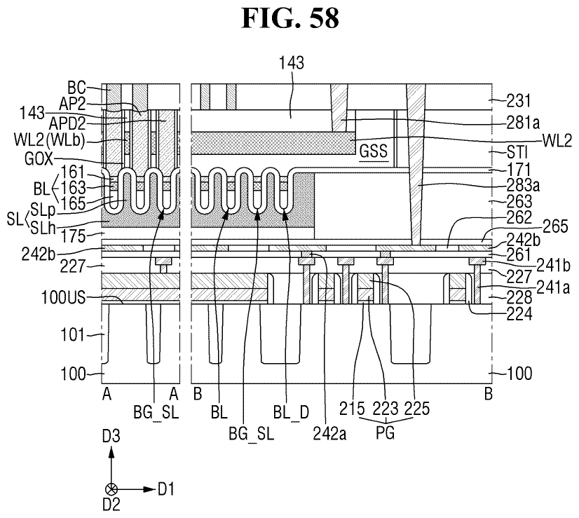

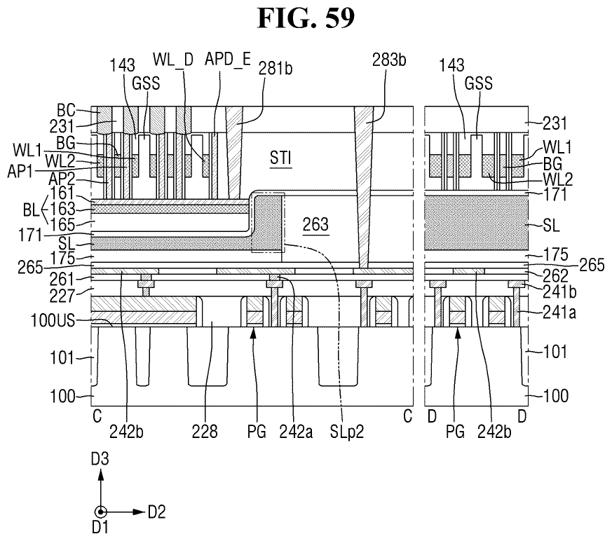

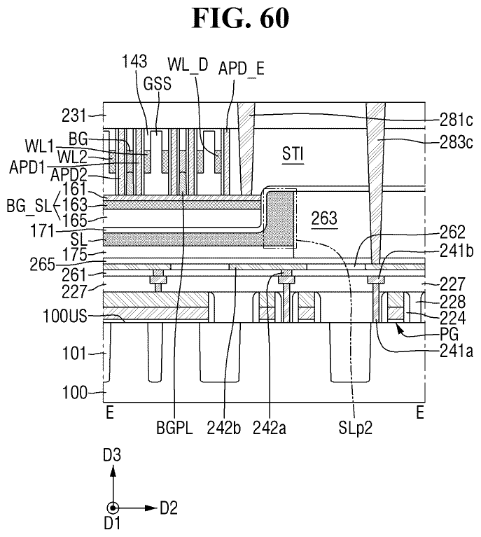

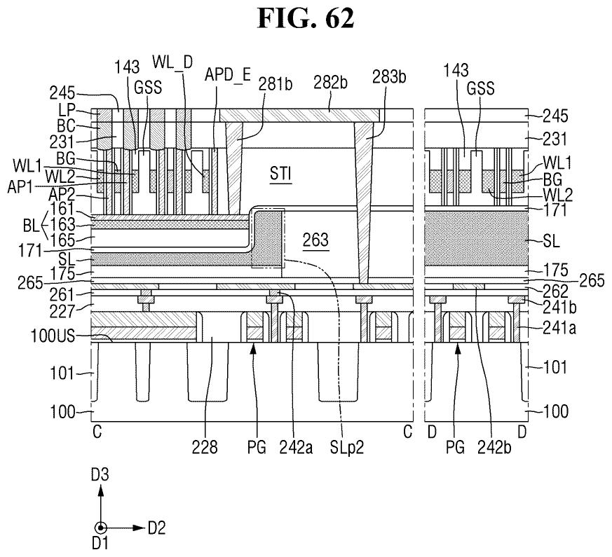

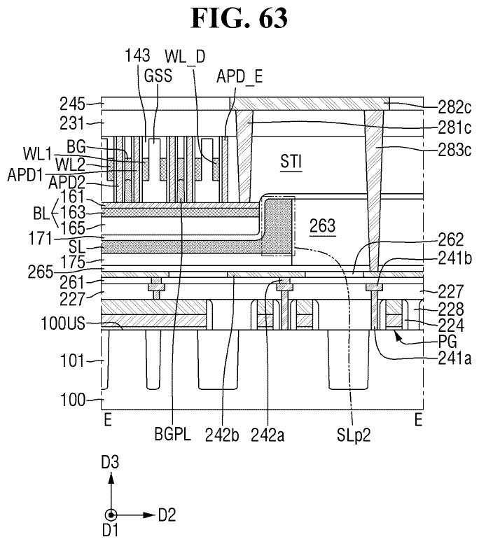

FIGS. 31 to 63 are diagrams for explaining a method for fabricating a semiconductor memory device according to some embodiments. Accordingly, the semiconductor memory device described using FIGS. 1 to 14 may be fabricated.

FIGS. 31 to 33, a sub-substrate structure including a sub-substrate 200, a buried insulating film 201 and an active layer 202 may be provided.

The buried insulating film 201 and the active layer 202 may be provided on the sub-substrate 200. The sub-substrate 200, the buried insulating film 201 and the active layer 202 may be silicon-on-insulating substrates (e.g., SOI substrates).

The sub-substrate 200 may include a cell array region CAR and a peripheral circuit region PCR. The sub-substrate 200 may be, for example, a silicon substrate, a germanium substrate, and/or a silicon-germanium substrate.

The buried insulating film 201 may be a buried oxide (BOX) formed by a SIMOX (separation by implanted oxygen) method or a bonding and layer transfer method. In contrast, the buried insulating film 201 may be an insulating film formed by a chemical vapor deposition method. The buried insulating film 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a monocrystalline silicon substrate, a germanium substrate, and/or a silicon-germanium substrate. The active layer 202 may have a first face and a second face opposite to each other in the third direction D3, and the second face of the active layer 202 may be in contact with the buried insulating film 201.

A plurality of active pattern separation structures AP_S1 may then be formed in the active layer 202. The active pattern separation structures AP_S1 may be arranged in the second direction D2. The active pattern separation structure AP_S1 may include, for example, silicon oxide. From the viewpoint of a plan view, the active pattern separation structure AP_S1 is shown to be a square, but is not limited thereto. Unlike the shown example, the active pattern separation structure AP_S1 may have shapes such as a square with rounded corners, an oval, and a circle.

A mask pattern MP may then be formed on the active layer 202 and the active pattern separation structure AP_S1. The mask pattern MP may include a lower mask film 11 and an upper mask film 12 that are sequentially stacked. The upper mask film 12 may be made of a material having etching selectivity with respect to the lower mask film 11. As an example, the lower mask film 11 may include silicon oxide, and the upper mask film 12 may include silicon nitride, but are not limited thereto.

Subsequently, a cell region element separation film STI may be formed inside the active layer 202 of the peripheral circuit region PCR. The cell region element separation film STI may be formed by patterning the active layer 202 of the peripheral circuit region PCR to form an element separation trench for exposing the buried insulating film 201, and then filling the element separation trench with an insulating material. The cell region element separation film STI may be formed to define a cell array region CAR. The upper face of the cell region element separation film STI may be substantially coplanar with the upper face of the mask pattern MP. The active pattern separation structure AP_S1 is disposed inside the cell array region CAR.

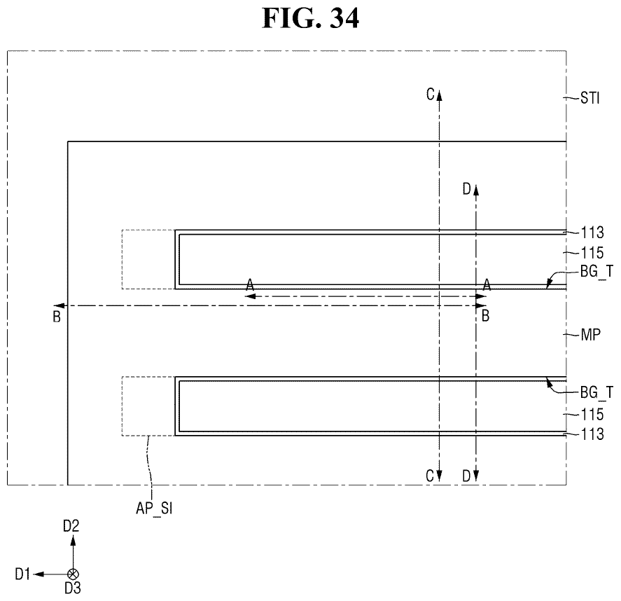

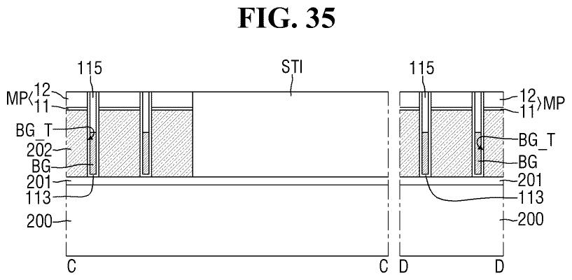

Referring to FIGS. 34 and 35, the active layer 202 of the cell array region CAR may be anisotropically etched.

Accordingly, the back gate trenches BG_T extending in the first direction D1 may be formed in the active layer 202 of the cell array region CAR. The back gate trenches BG_T may expose the buried insulating film 201, and may be spaced apart in the second direction D2 at regular intervals. Each back gate trench BG_T may be joined to each active pattern separation structure AP_S1.

Unlike the shown example, at least a part of the buried insulating film 201 may be removed, while the back gate trench BG_T is being formed.

The back gate insulating pattern 113 and the back gate electrodes BG may then be formed inside the back gate trench BG_T. The back gate insulating pattern 113 may be in contact with the active pattern separation structure AP_S1.

More specifically, the back gate insulating pattern 113 may be formed along the side walls and bottom face of the back gate trench BG_T and the upper face of the back gate mask pattern MP. A back gate conductive film may be formed on the back gate insulating pattern 113. The back gate conductive film may fill the back gate trench BG_T. Subsequently, the back gate conductive film may be etched to form the back gate electrodes BG extending in the first direction D1. The back gate electrodes BG may partially fill the back gate trench BG_T.

Meanwhile, according to some embodiments, a gas phase doping (GPD) process or a plasma doping (PLAD) process may be performed, before forming the back gate insulating pattern 113. The active layer 302 exposed by the back gate trench BG_T may be doped with impurities through the above processes.

The back gate capping patterns 115 may then be formed on the back gate electrode BG.

The back gate capping pattern 115 may fill the rest of the back gate trench BG_T. If the back gate capping pattern 115 and the back gate insulating pattern 113 are made of the same material (e.g., silicon oxide), the back gate insulating pattern 113 on the upper face of the back gate mask pattern MP may be removed during formation of the back gate capping pattern 115.

Meanwhile, before forming the back gate capping pattern 115, the gas phase doping (GPD) process or the plasma doping (PLAD) process may be performed. Accordingly, impurities may be doped into the active layer 302 through the back gate trench BG_T in which the back gate electrode BG is formed.

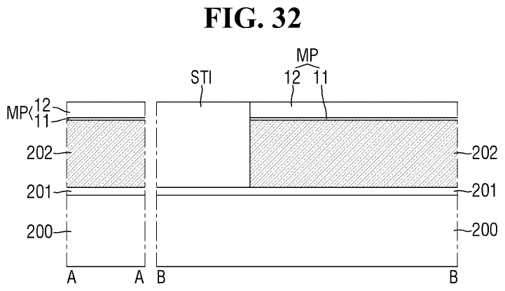

The cross-sectional view taken along A-A and B-B of FIG. 34 may be the same as that of FIG. 32.

Referring to FIGS. 34 to 38, after forming the back gate capping patterns 115, the upper mask film 12 may be removed.

The back gate capping patterns 115 may have a form that protrudes above the upper face of the lower mask film 11.

A pair of spacer patterns 121 may then be formed on side walls of the back gate insulating pattern 113.

More specifically, the spacer film may be formed along the upper face of the lower mask film 11, the side walls of the back gate insulating patterns 113, and the upper faces of the back gate capping patterns 115. The spacer film may be formed to have a uniform thickness. The spacer pattern 121 may be formed by performing an anisotropic etching process on the spacer film. The active layer 202 may be exposed, while the spacer patterns 121 are formed.

The widths of the active patterns of the vertical channel transistors may be determined depending on the deposited thickness of the spacer film. The spacer film may be made of an insulating material. The spacer film may include, for example, silicon oxide, silicon oxynitride, silicon nitride, silicon carbide (SiC), silicon carbon nitride film (SiCN), combinations thereof, and the like.

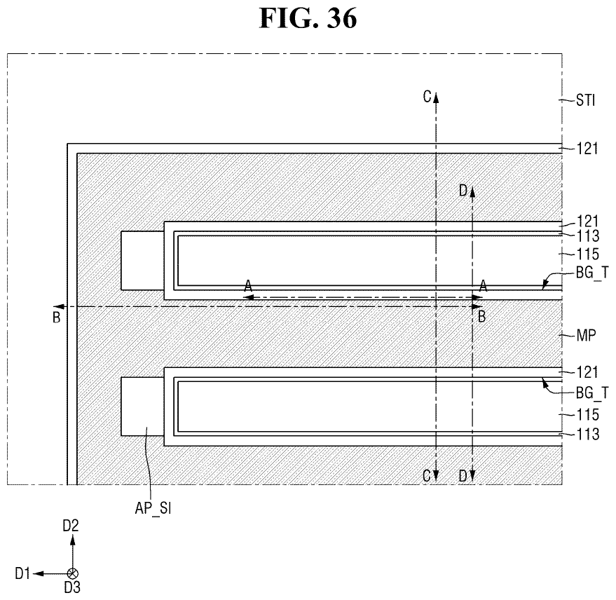

Referring to FIGS. 36 to 41, an anisotropic etching process may be performed on the active layer 202, using the spacer pattern 121 as an etching mask.

Accordingly, pre-active patterns PAP extending along each back gate electrode BG may be formed. The buried insulating film 201 may be exposed, as the pre-active patterns PAP are formed. The pre-active pattern PAP may be formed along side walls of the cell region element separation film STI.

By disposing the active pattern separation structure AP_S1, each pre-active pattern PAP may have a line shape extending along the side wall of the back gate electrode BG. A word line trench WL_T may be formed between the pre-active patterns PAP adjacent to each other.

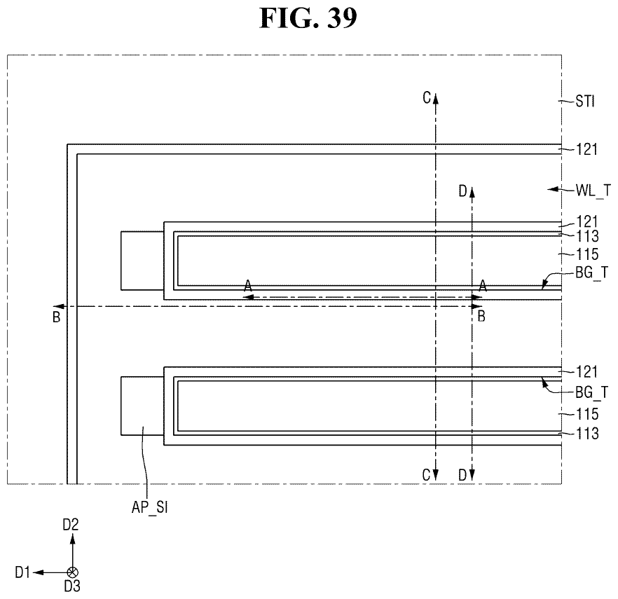

Referring to FIGS. 39 to 44, a sacrificial film that fills the word line trench WL_T may be formed.

An active mask pattern may be formed on the sacrificial film. The active mask pattern may have a line shape extending in the second direction D2. As another example, the active mask pattern may have a line shape extending in the oblique direction with respect to the first direction D1 and the second direction D2. The sacrificial film may be etched using the active mask pattern as an etch mask to form sacrificial openings inside the sacrificial film.

By etching the pre-active patterns PAP exposed to the sacrificial openings, a first active pattern AP1 and a second active pattern AP2 may be formed on both sides of the back gate electrode BG. The first active patterns AP1 may be formed to be spaced apart from each other in the first direction D1 on the first side wall of the back gate electrode BG. The second active patterns AP2 may be formed to be spaced apart from each other in the first direction D1 on the second side wall of the back gate electrode BG. As the first active pattern AP1 and the second active pattern AP2 are formed, the sacrificial openings may expose a part of the back gate insulating pattern 113.

In addition, the first dummy active pattern APD1 and the second dummy active pattern APD2 may be formed on both sides of the back gate electrode BG. The first dummy active pattern APD1 may be spaced apart from the first active pattern AP1 in the first direction D1. The second dummy active pattern APD2 may be spaced apart from the second active pattern AP2 in the first direction D1.

Thereafter, the sacrificial film, the active mask pattern, the spacer pattern 121 and the lower mask film 11 may be removed. Accordingly, the first active pattern AP1, the second active pattern AP2, the first dummy active pattern APD1, and the second dummy active pattern APD2 may be exposed. Also, the buried insulating film 201 may be exposed.

While forming the first active pattern AP1, the second active pattern AP2, the first dummy active pattern APD1 and the second dummy active pattern APD2, the boundary dummy active pattern APD_E may be formed on the side wall of the cell region element separation film STI. As an example, the boundary dummy active pattern APD_E may not be formed on the side walls of the cell region element separation film STI, unlike the shown example. As another example, the first dummy active pattern APD1 and the second dummy active pattern APD2 may not be formed on both sides of the back gate electrode BG.

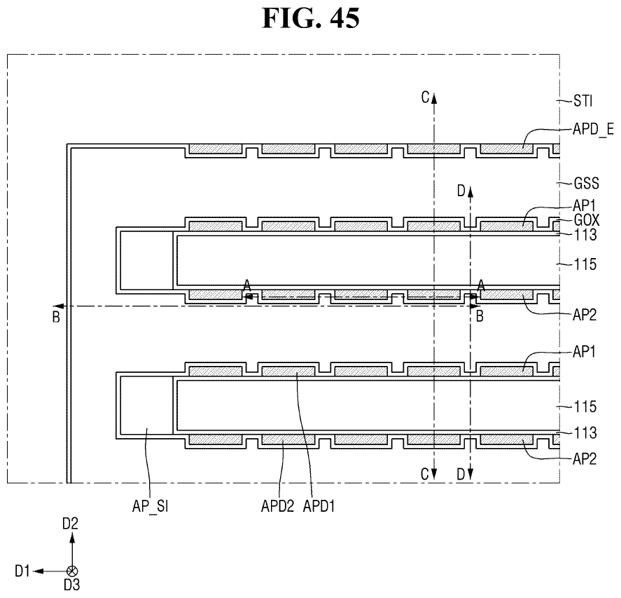

Referring to FIGS. 45 to 47, the gate insulating pattern GOX may be formed along side walls of the first active pattern AP1, side walls of the second active pattern AP2, side walls of the first dummy active pattern APD1, side walls of the second dummy active pattern APD2, an upper face of the gate capping pattern 115, and an upper face of the buried insulating film 201.

The gate insulating pattern GOX may be formed, but not limited to, using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a first word line WL1 and a second word line WL2 may be formed on the gate insulating pattern GOX. The first and second word lines WL1 and WL2 may be formed on side walls of the first and second active patterns AP1 and AP2. The dummy word line may be formed on side walls of the dummy active pattern AP_D.

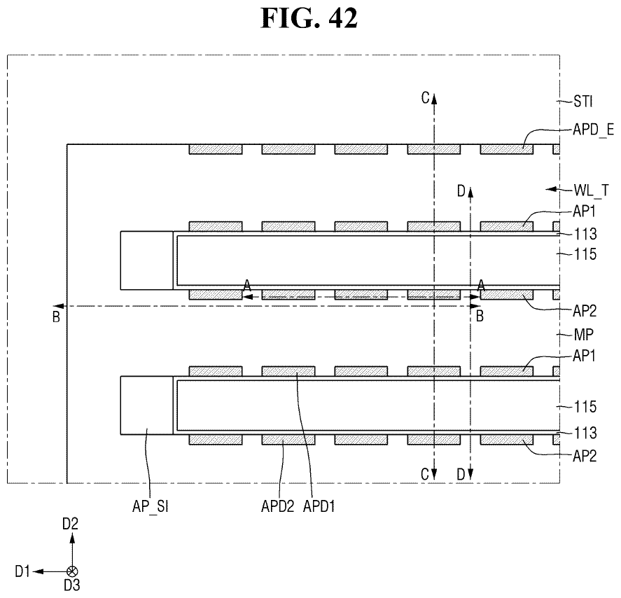

Formation of the first and second word lines WL1 and WL2 may include performing of the anisotropic etching process on the gate conductive film, after deposition of the gate conductive film on the gate insulating pattern GOX. Here, a deposition thickness of the gate conductive film may be smaller than half the width of the word line trench (WL_T of FIGS. 42 to 44).

At the time of the anisotropic etching process for the gate conductive film, the gate insulating pattern GOX may be used as an etching stop film. Unlike the shown example, the gate insulating pattern GOX may be over-etched to expose the buried insulating film 201. The first and second word lines WL1 and WL2 may have various shapes depending on the anisotropic etching process for the gate conductive film.

The upper face of the first word line WL1 and the upper face of the second word line WL2 may be positioned at a level lower than the upper faces of the first and second active patterns AP1 and AP2.

As an example, after forming the first and second word lines WL1 and WL2, a gas phase doping (GPD) process or a plasma doping (PLAD) process may be performed. As a result, impurities may be doped into the first and second active patterns AP1 and AP2 through the gate insulating pattern GOX exposed by the first and second word lines WL1 and WL2. While the first and second active patterns AP1 and AP2 are being doped with impurities, the first and second dummy active patterns APD1 and APD2 may be doped with impurities.

Subsequently, the gate separation pattern GSS may be formed on the first word line WL1 and the second word line WL2. For example, the upper face of the gate separation pattern GSS may be disposed on the same plane as the upper face of the back gate capping pattern 115.

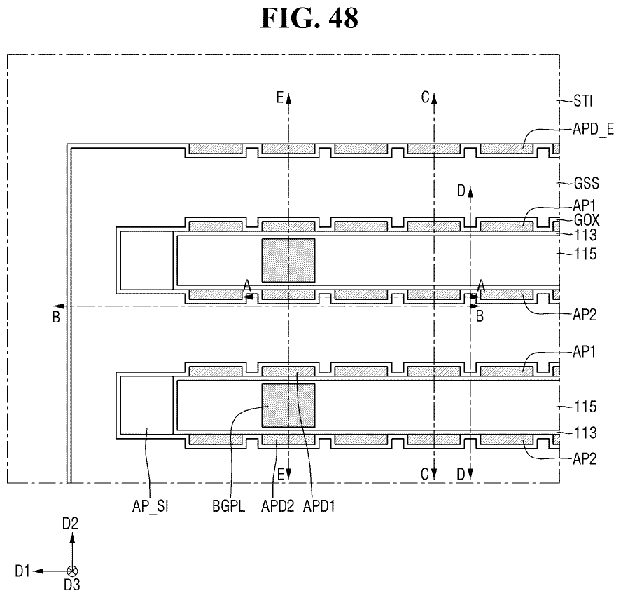

Referring to FIGS. 48 to 51, a back gate contact plug BGPL may be formed on the back gate electrode BG.

The back gate contact plug BGPL is connected to the back gate electrode BG. The back gate contact plug BGPL may be formed inside the back gate capping pattern 115. The back gate contact plug BGPL may pass through the back gate capping pattern 115 and be connected to the back gate electrode BG.

More specifically, a back gate contact hole for exposing a part of the back gate electrode BG may be formed inside the back gate capping pattern 115. The back gate contact hole may be formed between the first dummy active pattern APD1 and the second dummy active pattern APD2 adjacent to each other in the second direction D2. The back gate contact plug BGPL may fill the back gate contact hole.

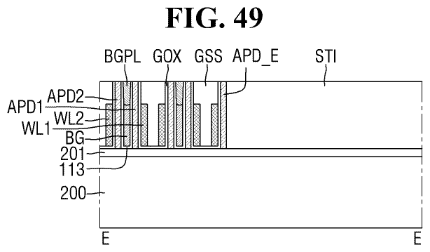

In FIGS. 48 and 49, the back gate contact plugs BGPL may be aligned in the second direction D2. When the back gate electrode BG includes one side and the other side spaced apart from each other in the first direction D1, each back gate contact plug BGPL may be connected to one side of the back gate electrode BG in the entire back gate electrode BG.

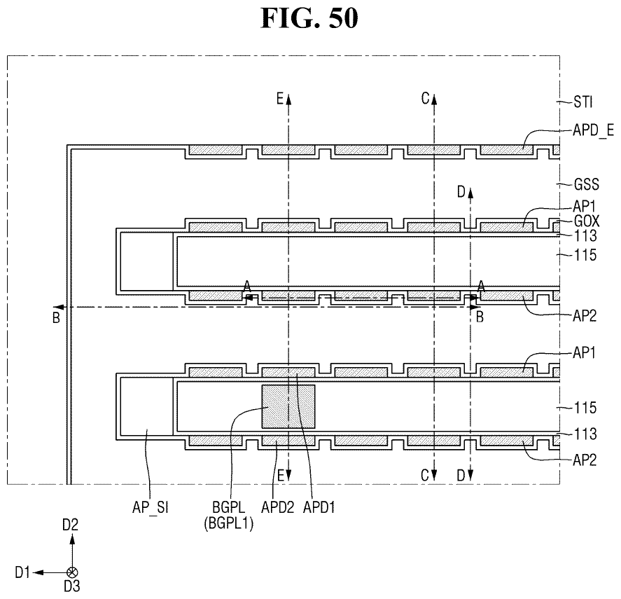

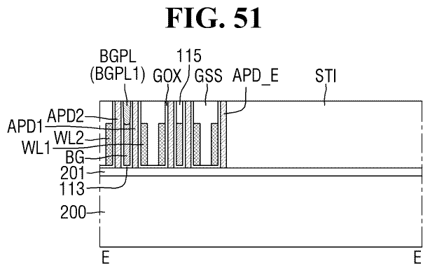

In FIGS. 50 and 51, the back gate contact plug BGPL may be arranged in zigzag as shown in FIG. 14. The back gate electrode BG may include one side and the other side spaced apart in the first direction D1. Among the two back gate electrodes BG adjacent in the second direction D2, one back gate electrode BG is connected to the back gate contact plug BGPL on one side of the back gate electrode BG, and the other back gate electrode BG may be connected to the back gate contact plug BGPL on the other side of the back gate electrode BG. For example, the first back gate contact plug BGPL1 may be connected to the back gate electrode BG on one side of the back gate electrode BG. Although not shown, the second back gate contact plug may be connected to the back gate electrode BG on the other side of the back gate electrode BG.

Fabricating processes to be performed subsequently will be described as proceeding on the back gate contact plug BGPL shown in FIGS. 48 and 49.

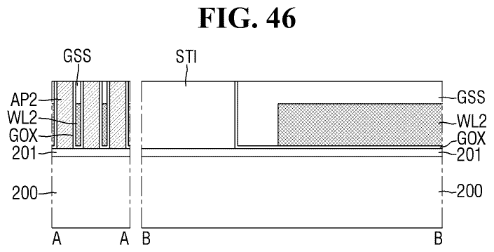

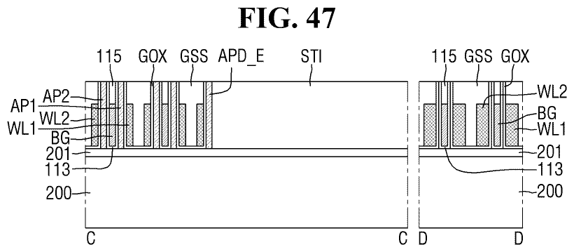

The cross-sectional views taken along A-A, B-B, C-C and D-D of FIGS. 48 and 50 may be the same as those of FIGS. 46 and 47.

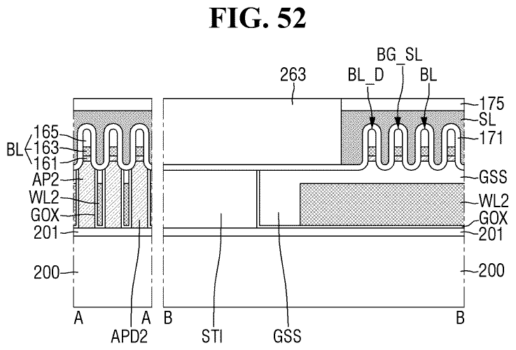

Referring to FIGS. 52 to 54, the bit line BL, the back gate strap line BG_SL, and the dummy bit line BL_D may be formed on first and second active patterns AP1 and AP2 and first and second dummy active patterns APD1 and APD2.

The bit line BL may be formed on the first active pattern AP1 and the second active pattern AP2. The bit line BL may be connected to the first active pattern AP1 and the second active pattern AP2.

The back gate strap line BG_SL may be formed on the first dummy active pattern APD1 and the second dummy active pattern APD2. The back gate strap line BG_SL may be connected to the back gate contact plug BGPL.

The shielding insulation liner 171 may then be formed along the profile of the bit line BL, the profile of the back gate strap line BG_SL, and the profile of the dummy bit line BL_D. The shielding conductive pattern SL and the shielding insulation capping film 175 may be formed on the shielding insulation liner 171.

Subsequently, the first upper insulating film 263 may be formed on the shielding insulation liner 171. The first upper insulating film 263 may cover side walls of the shielding conductive pattern SL and side walls of the shielding insulation capping film 175. The upper face of the first upper insulating film 263 may be coplanar with the upper face of the shielding insulation capping film 175.

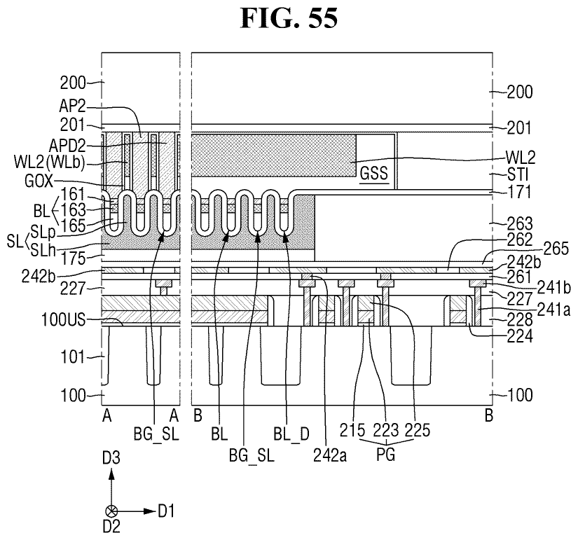

Referring to FIGS. 55 to 57, a sub-substrate 200 having the back gate electrodes BG, the word lines WL1 and WL2, the active patterns AP1 and AP2, the bit lines BL, the back gate strap line BG_SL, and the shielding conductive pattern SL formed thereon may be bonded to the substrate 100.

Alternatively, the substrate 100 on which the peri-gate structure PG and the peri-connection structures 242a and 242b are formed may be bonded to the sub-substrate 200.

Referring to FIGS. 55 to 60, after bonding the sub-substrate 200 and the substrate 100, a back lapping process for removing the sub-substrate 200 may be performed.

Removal of the sub-substrate 200 may include sequentially performing a grinding process and a wet etching process to expose the buried insulating film 201.

Next, the buried insulating film 201 may be removed to expose the first active pattern AP1, the second active pattern AP2, the first dummy active pattern APD1 and the second dummy active pattern APD2.

The buried insulating film 201 may be removed to expose a part of the gate insulating pattern GOX and a part of the back gate insulating pattern 113.

After that, the exposed gate insulating pattern GOX and the exposed back gate insulating pattern 113 may be removed. Accordingly, the back gate electrode BG, the first word line WL1 and the second word line WL2 may be exposed.

An etch-back process may then be performed to remove a part of the first word line WL1 and a part of the second word line WL2. The gate capping pattern 143 may be formed on the recessed first and second word lines WL1 and WL2.

A part of the back gate electrode BG may be removed by performing the etch-back process. The back gate separation pattern 111 may be formed on the recessed back gate electrode BG.

A contact hole for exposing the first active pattern AP1 and the second active pattern AP2 may be formed inside the contact interlayer insulating film 231.

The contact pattern BC may be formed inside the contact hole. The contact patterns BC may be formed on the first active pattern AP1 and the second active pattern AP2. The contact patterns BC may be connected to the first active pattern AP1 and the second active pattern AP2.

Also, word line contact plugs 281a connected to the word lines WL1 and WL2 may be formed. The bit line contact plug 281b connected to the bit line BL may be formed. The strap line contact plug 281c connected to the back gate strap line BG_SL may be formed. First to third upper peripheral contact plugs 283a, 283b and 283c may be formed. First to third upper peripheral contact plugs 283a, 283b and 283c connected to the peri-connection wiring 242b may be formed.

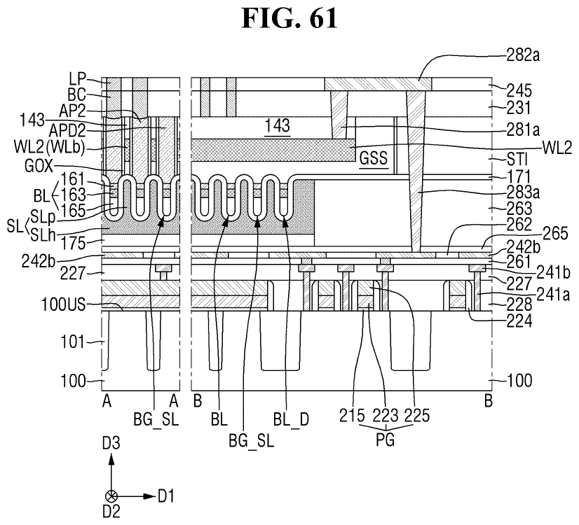

Referring to FIGS. 61 to 63, the landing pad LP may be formed on the contact pattern BC.

The landing pad LP may be formed inside the pad separation insulating film 245. The first to third upper connection wirings 282a, 282b and 282c may be formed inside the pad separation insulating film 245. The first upper connection wiring 282a may connect the word line contact plug 281a and the first upper peripheral contact plug 283a. The second upper connection wiring 282b may connect the bit line contact plug 281b and the second upper peripheral contact plug 283b. The third upper connection wiring 282c may connect the strap line contact plug 281c and the second upper peripheral contact plug 283c.

The data storage patterns DSP may then be formed on the landing pad LP.

In concluding the detailed description, those skilled in the art will appreciate that many variations and modifications may be made to example embodiments without substantially departing from the principles of inventive concepts. Therefore, the disclosed embodiments of the disclosure are used in a generic and descriptive sense only and not for purposes of limitation.

What is claimed is:

1. A semiconductor memory device comprising:
a substrate;
a bit line extending in a first direction on the substrate;
a back gate strap line on the substrate and extending in the first direction,
an active pattern on the bit line and the back gate strap line, the active pattern including a first side wall and a second side wall opposite each other in the first direction, a first face of the active pattern being opposite a second face of the active pattern in a vertical direction, the first face of the active pattern being connected to the bit line;
a word line on the first side wall of the active pattern and extending in a second direction;
a back gate electrode on the second side wall of the active pattern and extending in the second direction, the back gate electrode being connected to the back gate strap line;
a data storage pattern connected to the second face of the active pattern; and
a word line contact plug connected to the word line, wherein
a first face of the back gate electrode and a second face of the back gate electrode are opposite each other in the vertical direction,
a first face of the word line and a second face of the word line are opposite each other in the vertical direction,
the first face of the back gate electrode and the first face of the word line each face the bit line and the back gate strap line,
the first face of the back gate electrode is connected to the back gate strap line, and
the second face of the word line is connected to the word line contact plug.

2. The semiconductor memory device of claim 1, further comprising:
a back gate contact plug between the back gate strap line and the back gate electrode.

3. The semiconductor memory device of claim 2,
wherein a width of the back gate contact plug decreases as it goes away from the back gate strap line.

4. The semiconductor memory device of claim 2, further comprising:
a plug spacer on a side wall of the back gate contact plug.

5. The semiconductor memory device of claim 2,
wherein the back gate contact plug includes at least one of a metal and a conductive semiconductor material.

6. The semiconductor memory device of claim 1, further comprising:
a dummy active pattern on the back gate strap line, wherein
the dummy active pattern is spaced apart from the active pattern in the second direction, and
the dummy active pattern is in contact with the back gate strap line.

7. The semiconductor memory device of claim 6,
wherein a length of the dummy active pattern in the second direction is greater than a length of the active pattern in the second direction.

8. The semiconductor memory device of claim 1, further comprising:
a shielding conductive pattern on the substrate,
wherein the shielding conductive pattern includes a shielding conductive plate and a plurality of shielding conductive protruding parts protruding from the shielding conductive plate,
each of the plurality of shielding conductive protruding parts extends in the first direction, and
the bit line is between the shielding conductive protruding parts adjacent to each other in the second direction.

9. The semiconductor memory device of claim 8,
wherein the back gate strap line is between the shielding conductive protruding parts adjacent to each other in the second direction.

10. The semiconductor memory device of claim 1, further comprising:
a dummy bit line on the substrate,
wherein the back gate strap line is between the dummy bit line and the bit line.

11. The semiconductor memory device of claim 1,
wherein the back gate electrode includes at least one of a metal and a conductive semiconductor material.

12. A semiconductor memory device comprising:
a substrate;
bit lines extending in a first direction on the substrate;
a first back gate strap line on the substrate, the first back gate strap line extending in the first direction;
back gate electrodes on the bit lines and the first back gate strap line, the back gate electrodes extending in a second direction;
a first word line and a second word line on the bit line and the first back gate strap line, the first word line and the second word line between the back gate electrodes adjacent to each other in the first direction, and the first word line the second word line extending in the second direction;
first active patterns between the back gate electrode and the first word line, the first active patterns arranged in the second direction;
second active patterns between the back gate electrode and the second word line, the second active patterns arranged in the second direction;
a back gate contact plug between the first back gate strap line and one or more back gate electrodes, and the back gate contact plug connecting the first back gate strap line and the back gate electrode to each other;
a word line contact plug on the first word line and connected to the first word line; and
a data storage pattern on the first active pattern and the second active pattern, the data storage pattern connected to the first active pattern and the second active pattern, wherein
the first word line is between the word line contact plug and the first back gate strap line.

13. The semiconductor memory device of claim 12, further comprising:
a second back gate strap line on the substrate and extending in the first direction, wherein
the bit line is between the first back gate strap line and the second back gate strap line,
the back gate electrodes include a first back gate electrode and a second back gate electrode,
the first back gate strap line is connected to the first back gate electrode, and
the second back gate strap line is connected to the second back gate electrode.

14. The semiconductor memory device of claim 12,
wherein the first back gate strap line is connected to each of the back gate electrodes.

15. The semiconductor memory device of claim 12,
wherein a width of the back gate contact plug decreases as it goes away from the first back gate strap line.

16. The semiconductor memory device of claim 12, further comprising:
a shielding conductive pattern on the substrate,
wherein the shielding conductive pattern includes a shielding conductive plate and a plurality of shielding conductive protruding parts protruding from the shielding conductive plate,
each of the plurality of shielding conductive protruding parts extend in the first direction, and
a bit line among the bit lines and the first back gate strap line are between the shielding conductive protruding parts adjacent to each other in the second direction.

17. The semiconductor memory device of claim 12, further comprising:
a dummy active pattern on the first back gate strap line, wherein
the dummy active pattern is spaced apart from a corresponding one of the first active patterns in the second direction, and
the dummy active pattern is in contact with the first back gate strap line.

18. The semiconductor memory device of claim 12, further comprising:
a dummy bit line on the substrate,
wherein the first back gate strap line is between the dummy bit line and a corresponding one of the bit lines.

19. A semiconductor memory device comprising:
a substrate;
a peri-gate structure on the substrate;
a shielding conductive pattern on the peri-gate structure, the shielding conductive pattern including a shielding conductive plate and a plurality of shielding conductive protruding parts protruding from the shielding conductive plate, each of the shielding conductive protruding parts extending in a first direction;
a first back gate strap line and a second back gate strap line on the shielding conductive pattern and extending in the first direction;
bit lines between the first back gate strap line and the second back gate strap line, the bit lines on the shielding conductive pattern and extending in the first direction;
back gate electrodes on the bit line, the first back gate strap line, and the second back gate strap line, the back gate electrodes extending in a second direction;
a first word line and a second word line between the back gate electrodes adjacent to each other in the first direction,
the first word line and the second word line being on the bit line, the first back gate strap line and the second back gate strap line, and
the first word line and the second word line extending in the second direction;
first active patterns between the back gate electrode and the first word line, the first active patterns being connected to the bit line and arranged in the second direction;
second active patterns between the back gate electrode and the second word line, the second active patterns being connected to the bit line and arranged in the second direction;
a first back gate contact plug between the first back gate strap line and a part of the back gate electrodes, the first back contact plug connecting the first back gate strap line and the back gate electrode to each other;
a second back gate contact plug between the second back gate strap line and a rest of the back gate electrode, the second back contact plug connecting the second back gate strap line and the back gate electrode to each other;
a word line contact plug on the first word line and connected to the first word line; and
a data storage pattern on the first active pattern and the second active pattern, the data storage pattern being connected to the first active pattern and the second active pattern,
wherein the first word line includes a first face and a second face opposite each other in a vertical direction,
the first face of the first word line faces the bit line, and
the word line contact plug is connected to the second face of the first word line.

20. The semiconductor memory device of claim 19, further comprising:
dummy active patterns on the first back gate strap line and arranged in the first direction,
wherein the first back gate strap line is in contact with the dummy active pattern.
